(19) United States
(12) Patent Application Publication
(10) Pub. No.: US 2026/0234315 A1
(43) Pub. Date: Aug. 13, 2026

(54) MODIFIED OLEFINIC COPOLYMER, RESIN COMPOSITION, LAMINATED SHEET, PREPREG, CURED ARTICLE, SUBSTRATE WITH CURED ARTICLE, AND ELECTRONIC APPARATUS

(71) Applicants: artience Co., Ltd., Chuo-ku, Tokyo (JP); TOYOCHEM CO., LTD., Chuo-ku, Tokyo (JP)

(72) Inventors: Kenji OSHIMA, Chuo-ku, Tokyo (JP); Go SAKAGUCHI, Chuo-ku, Tokyo (JP); Takashi ISHIKAWA, Chuo-ku, Tokyo (JP)

(73) Assignees: artience Co., Ltd., Chuo-ku, Tokyo (JP); TOYOCHEM CO., LTD., Chuo-ku, Tokyo (JP)

(21) Appl. No.: 19/153,383

(22) PCT Filed: Feb. 26, 2024
(86) PCT No.: PCT/JP2024/006748

§ 371 Date: Aug. 4, 2025

(30) Foreign Application Priority Data
Feb. 27, 2023 (JP) 2023-028746
Nov. 29, 2023 (JP) 2023-202239

(51) Int. Cl. C08F 290/04; C08J 5/24; C08K 3/013

(52) U.S. Cl. CPC C08F 290/04; C08J 5/24; C08K 3/013; C08J 2309/00

(57) ABSTRACT

A modified olefinic copolymer, a resin composition, a laminated sheet, a prepreg, a cured article, a substrate with a cured article, and an electronic apparatus having an excellent dielectric characteristic, excellent heat resistance, and excellent crack resistance are provided. A modified olefinic copolymer in which a principal chain contains a structural unit derived from a conjugated diene compound and/or a structural unit derived from an alicyclic or chain-like non-conjugated olefin compound, in which the modified olefinic copolymer has a monocyclic structure and/or a polycyclic structure in at least one of a side group, a side chain, and a molecular chain end, and a ring of the monocyclic structure and/or one of rings of the polycyclic structures is at least one of an alicyclic skeleton including carbon atoms and an alicyclic skeleton including carbon and hetero atoms, and has a radically reactive non-conjugated carbon-carbon unsaturated bond.

### TECHNICAL FIELD

The present disclosure relates to a modified olefinic copolymer, a resin composition, a laminated sheet, and a prepreg. Further, the present disclosure relates to a cured article obtained from the aforementioned resin composition, a substrate with a cured article formed by curing the aforementioned resin composition, and an electronic apparatus on which the aforementioned substrate with the cured article is mounted.

### BACKGROUND

Resin compositions or cured articles of resin compositions are used in various members of electronic components. For example, a resin composition or a cured article thereof is used as an interlayer insulating layer between conductor layers of a multilayered printed wiring board. Further, a prepreg which is obtained by impregnating a glass cloth or the like with a resin composition is used as an insulating layer on a conductor layer of a printed wiring board. Further, an insulating resin composition or a cured article thereof is used as a sealing resin for a semiconductor package.

As such a resin composition, for example, Patent Literature 1 discloses a resin composition containing a maleimide compound (A) having two or more N-substituted maleimide groups, a polyphenylene ether (B), and a copolymer (C) having a structural unit derived from a styrene-based compound, a structural unit derived from maleic anhydride, and a structural unit derived from an N-substituted maleimide. Further, Patent Literature 2 discloses a thermosetting cyclic imide resin composition containing (A) a styrene-based elastomer, (B) a cyclic imide compound having a specific structure, (C) an epoxy resin, and (D) a reaction accelerator in a specific ratio. Further, Patent Literature 3 discloses a thermoplastic elastomer having a side chain containing a hydrogen-bond cross-linking part having a specific structure and another side chain containing a covalent-bond cross-linking part. Patent Literature 4 discloses a thermoplastic elastomer composition containing: in a specific ratio, at least one type of elastomer component selected from the group consisting of an elastomeric polymer (A) having a side chain (a) containing a hydrogen-bond cross-linking part having a specific structure and having a Tg of 25° C. or lower, an elastomeric polymer (B) containing a hydrogen-bond cross-linking part and a covalent-bond cross-linking part in a side chain and having a Tg of 25° C. or lower; clay; and an α-olefinic resin having no chemical-bond cross-linking part.

### CITATION LIST

### Patent Literature

Patent Literature 1: Japanese Unexamined Patent Application Publication No. 2020-169276
Patent Literature 2: Japanese Unexamined Patent Application Publication No. 2022-111423
Patent Literature 3: Japanese Unexamined Patent Application Publication No. 2006-131663
Patent Literature 4: International Patent Publication No. WO2017/047274

### SUMMARY

As functions of electronic apparatuses have becoming more sophisticated, there is an increasing demand for reliability of electronic components provided in such apparatuses. In resin compositions and cured articles thereof, there is a demand for materials that have not only excellent heat resistance but also excellent crack resistance after a heat cycle test. Further, there is a demand for materials which have a low dielectric constant and a low dielectric tangent, and are capable of supporting gigahertz bands as frequency bands of signals used in printed wiring boards used for electronic apparatuses, communication apparatuses, and the like. In the market, there is a demand for resins and resin compositions which can improve crack resistance after a heat cycle test while satisfying both a dielectric characteristic and a heat resistance characteristic.

The present disclosure has been made in view of the above-described background, and an object thereof is to provide a modified olefinic copolymer and a resin composition having an excellent dielectric characteristic, excellent heat resistance, and excellent crack resistance after a heat cycle test, and to provide a laminated sheet, a prepreg, a cured article, a substrate with a cured article, and an electronic apparatus formed by using the resin composition.

The inventors of the present disclosure have diligently studied, and as a result, have found that the problem of the present disclosure can be solved in the below-shown aspects and completed the present disclosure.

[1]: A modified olefinic copolymer in which a principal chain contains a structural unit derived from a conjugated diene compound and/or a structural unit derived from an alicyclic or chain-like non-conjugated olefin compound, in which
the modified olefinic copolymer has a monocyclic structure and/or a polycyclic structure in at least one of a side group, a side chain, and a molecular chain end, and
a ring of the monocyclic structure and/or one of rings of the polycyclic structure is at least one of an alicyclic skeleton consisting of carbon atoms and an alicyclic skeleton consisting of carbon and hetero atoms, and satisfies at least one of below-shown conditions (i) and (ii):
(i) the alicyclic skeleton has a radically reactive non-conjugated carbon-carbon unsaturated bond; and
(ii) a carbon atom constituting the alicyclic skeleton and a carbon atom not constituting the ring bonded to the carbon atom are bonded to each other by a radically reactive non-conjugated carbon-carbon unsaturated bond.
   [2]: The modified olefinic copolymer described in Item [1], in which the principal chain has substantially no unsaturated bond except for the molecular chain end.
   [3]: The modified olefinic copolymer described in Item [1] or [2], in which the principal chain contains a structural unit derived from an aromatic vinyl compound.
   [4]: The modified olefinic copolymer described in any one of Items [1] to [3], further containing a block consisting of a structural unit derived from an aromatic vinyl compound and a block consisting of a structural unit derived from a conjugated diene compound.
   [5]: The modified olefinic copolymer described in Item [4], in which the block consisting of the structural unit derived from the conjugated diene compound further contains a structural unit derived from an aromatic vinyl compound.
   [6]: The modified olefinic copolymer described in any one of Items [1] to [5], in which
the modified olefinic copolymer is a hydrogenated styrene-based elastomer, and
is a modified form of one of a styrene-ethylene-butylene block copolymer (SEB), a styrene-ethylene-propylene block copolymer (SEP), a styrene-ethylene-butylene-styrene block copolymer (SEBS), a styrene-ethylene-propylene-styrene block copolymer (SEPS), a styrene-ethylene-butylene styrene-styrene block copolymer (SEBSS), a styrene-isobutylene-styrene block copolymer (SIBS), and a styrene-ethylene-ethylene propylene styrene block copolymer (SEEPS).
   [7]: A resin composition containing a modified olefinic copolymer described in any one of Items [1] to [6].
   [8]: The resin composition described in Item [7], further containing a curable compound, in which the curable compound contains at least one compound selected from an epoxy compound (b1), a cyanate ester compound (b2), a maleimide compound (b3), an allyl group-containing compound (b4), a vinyl group-containing compound (b5), a (meth)acrylate group-containing compound (b6), and a benzoxazine compound (b7).
   [9]: The resin composition described in Item [7] or [8], further containing an inorganic filler.
   [10]: A laminated sheet including a base material and a resin composition layer formed on the base material using a resin composition described in any one of Items [7] to [9].
   [11]: A prepreg obtained by impregnating a base material with a resin composition described in any one of Items [7] to [9].
   [12]: A cured article obtained from a resin composition described in any one of Items [7] to [9].
   [13]: A substrate with a cured article obtained by curing a resin composition described in any one of Items [7] to [9].
   [14]: An electronic apparatus including the substrate with the cured article described in Item [13].

According to the present disclosure, it is possible to provide a modified olefinic copolymer and a resin composition having an excellent dielectric characteristic, excellent heat resistance, and excellent crack resistance after a heat cycle test, and to provide a laminated sheet, a prepreg, a cured article, a substrate with a cured article, and an electronic apparatus formed by using the resin composition.

### BRIEF DESCRIPTION OF DRAWINGS

FIG. 1 shows IR spectra of a resin R-5, Synthetic Example 5, and Comparative Synthetic Example 5.

### DETAILED DESCRIPTION OF EMBODIMENTS

The present disclosure will be described hereinafter in detail. Note that other embodiments are also included in the scope of the present disclosure as long as they are consistent with the intent of the present disclosure. Further, a numerical value range specified by using “-” in the specification of the present disclosure includes numerical values before and after “-” as a lower limit value and an upper limit value, respectively, of the range. Further, in the present specification, “film” and “sheet” are synonymous and are not distinguished by the thickness. Further, unless otherwise specified, each of components mentioned the specification of the present disclosure may be used independently, or two or more components may be used in combination. Values mentioned in the specification of the present disclosure refer to values obtained by a method described in [Examples](which will be described later).

### 1. Modified Olefinic Copolymer

In a modified olefinic copolymer according to the present disclosure (hereinafter also referred to as the copolymer disclosed herein), the principal chain contains a structural unit derived from a conjugated diene compound and/or a structural unit derived from an alicyclic or chain-like non-conjugated olefin compound. In order to further improve the dielectric characteristic and the heat resistance, the principal chain preferably has substantially no unsaturated bond except for the molecular chain end. Note that the term “substantially not including” herein means that the principal chain has no unsaturated bond except for those that are unavoidably included therein. The copolymer disclosed herein has a monocyclic structure and/or a polycyclic structure in at least one of a side group, a side chain, and a molecular chain end thereof. Further, a ring of the monocyclic structure and/or one of rings of the polycyclic structure is at least one of an alicyclic skeleton consisting of carbon atoms and an alicyclic skeleton consisting of carbon and hetero atoms, and satisfies at least one of the below-shown conditions (i) and (ii). Note that the skeleton refers to a structure formed by atoms that directly form a ring. For example, in the case of a cycloalkenyl group, the atoms that directly form a ring are carbon atoms, and it includes no hydrogen. Further, in the case of a maleimide group, the atoms that directly form a ring are carbon atoms and a hetero atom (a nitrogen atom).
(i) the alicyclic skeleton has a radically reactive non-conjugated carbon-carbon unsaturated bond; and
(ii) a carbon atom constituting the alicyclic skeleton and a carbon atom not constituting the ring bonded to the carbon atom are bonded to each other by a radically reactive non-conjugated carbon-carbon unsaturated bond.

The aforementioned “structural unit derived from an alicyclic or chain-like non-conjugated olefin compound” in the principal chain refers to a structure in which the principal chain is composed of aliphatic hydrocarbon having no aromaticity (i.e., no 1L electron conjugated system). The copolymer disclosed herein having a structural unit derived from an alicyclic non-conjugated olefin compound has a ring structure in the principal chain. Note that the principal chain is a linear molecular chain that serves as a trunk in a polymer constituting a resin, and is a chain of carbon atoms. The principal chain may contain carbon atoms constituting an alicyclic structure consisting of hydrocarbon. From the standpoint of dielectric properties, it is preferable that the copolymer disclosed herein does not include a copolymer component having a ring containing a hetero atom in the main chain (e.g., a ring derived from a maleimide group). Further, in view of the crack resistance after a heat cycle test, the principal chain skeleton of the copolymer disclosed herein preferably has a chain-like structure rather than an alicyclic structure.

The “alicyclic skeleton” present in a monocyclic structure and/or a polycyclic structure in a side chain, a side group, or a molecular chain end refers to a ring structure having no aromaticity (i.e., no 11 electron conjugated system), such as a cyclic aliphatic hydrocarbon group, and the monocyclic structure and/or the polycyclic structure may have a maleimide group, a functional group such as a carbonyl group, and/or a substituent. The “monocyclic structure” refers to a structure having a monocyclic ring. It has one or more monocyclic rings. The “polycyclic structure” refers to a bridging structure (bridgehead structure), a condensed ring structure in which two or more monocyclic rings share only one side of each of the rings with each other (condensation), or a combination thereof. It is sufficient if the copolymer disclosed herein has a ring having an alicyclic skeleton, and a part of the monocyclic structure and/or a part of the polycyclic structure may contain an aromatic ring. The copolymer disclosed herein preferably contains no heterocycle.

The “radically reactive non-conjugated carbon-carbon unsaturated bond” in the conditions (i) and (ii) refers to a bond in which the modified olefinic copolymer can be covalently bonded to other modified olefinic copolymers and/or curable compounds by a radical reaction. The radical reaction can be induced, for example, by heating, light irradiation, or electron beam irradiation.

Since the copolymer disclosed herein has the above-described structure, it has excellent heat resistance. It is considered that the main reason for this is that the copolymer has the alicyclic skeleton in at least one of a side group, a side chain, and a molecular chain end thereof, and is bonded by a radically reactive non-conjugated carbon-carbon unsaturated bond, so that a crosslinked structure is formed by a curing process and hence the curing property is improved. In particular, since the copolymer has the alicyclic skeleton in a side chain and/or a side group, the steric hindrance is suppressed and the reactive property is improved. As a result, the curing property is improved.

Further, a cured article of a resin composition containing the copolymer disclosed herein has an excellent dielectric characteristic. It is considered that the main reason for this is that the copolymer has the alicyclic skeleton in at least one of a side group, a side chain, and a molecular chain end thereof, and contains a structural unit derived from a conjugated diene compound and/or a structural unit derived from an alicyclic or chain-like non-conjugated olefin compound, so that, by adopting a carbon-carbon bond at the cross-linking part, the polarization is reduced and the dielectric relaxation is suppressed compared to the case where the crosslinking is obtained through oxygen atoms or nitrogen atoms (e.g., compared to the case where the curing is carried out by using an epoxy compound). Further, since the copolymer has the alicyclic skeleton in at least one of a side chain, a side group, and a molecular chain end thereof, the steric hindrance is reduced and, therefore, the copolymer exhibits high reactivity, whereby the amount of non-conjugated carbon-carbon unsaturated bonds remaining after the curing reaction can be reduced. As a result, it is possible to suppress the generation of hydroxyl groups due to oxidation and the resultant decrease in the dielectric characteristic.

Further, since the cured article of a resin composition containing the copolymer disclosed herein has the above-described structure, it has excellent crack resistance after a heat cycle test. It is considered that the main reason for this is the structure in which by adopting a structural unit derived from a conjugated diene compound and/or an alicyclic or chain-like non-conjugated olefinic skeleton for the principal chain, the flexibility is improved, and the crosslinking structure is constructed by the carbon-carbon unsaturated bond of the alicyclic skeleton present in at least one of a side group, a side chain, and a molecular chain end thereof. From the viewpoint of more effectively improving flexibility, it is preferred that the principal chain comprises, as its main chain skeleton, a structural unit derived from a conjugated diene compound that substantially has no residual unsaturated bond, and/or an alicyclic or chain-like non-conjugated olefinic skeleton.

### 1-1. Main Chain Skeleton

In the copolymer disclosed herein, the principal chain comprises a structural unit derived from a conjugated diene compound and/or a structural unit derived from an alicyclic or chain-like non-conjugated olefin compound. In order to further improve the dielectric characteristic and the heat resistance, the principal chain preferably has substantially no unsaturated bond except for the molecular chain end. In this case, when unsaturated bonds remain in the principal chain skeleton, a copolymer containing substantially no unsaturated bond can be obtained by a hydrogenation reaction.

A monomer(s) for obtaining the structural unit derived from the conjugated diene compound constituting the principal chain of the copolymer disclosed herein (hereinafter also referred to as a monomer A) can be selected as appropriate from known monomers. Suitable examples include butadiene, isoprene, 2,3-dimethyl-butadiene, 2-phenyl-butadiene, 1,3-pentadiene, 2-methyl-1,3-pentadiene, 1,3-hexadiene, 1,3-octadiene, 1,3-cyclohexadiene, 2-methyl-1,3-octadiene, 1,3,7-octatriene, myrcene, farnesene, chloroprene, and mixtures thereof. Among them, butadiene and isoprene are more preferred.

A monomer(s) for obtaining a structural unit derived from an alicyclic or chain-like non-conjugated olefin compound constituting the principal chain of the copolymer disclosed herein (hereinafter also referred to as a monomer B) can be selected as appropriate from known monomers. Suitable examples include ethylene, propylene, α-olefins such as 1-pentene, 1-hexene, 1-heptene, and 1-octene, hetero atom-substituted alkene compounds such as N-vinylpyrrolidone, bicyclic compounds such as norbornene and norbornadiene, tricyclic compounds such as dicyclopentadiene and dihydrodicyclopentadiene, tetracyclic compounds such as tetracyclododecene, pentacyclic compounds such as tricyclopentadiene, heptacyclic compounds such as tetracyclopentadiene, and norbornene-based monomers such as derivatives of the aforementioned compounds. Among them, ethylene and propylene are preferred, and ethylene is particularly preferred.

In order to improve the mechanical strength and the heat resistance, the copolymer disclosed herein preferably has a structural unit derived from an aromatic vinyl compound in the principal chain. A monomer(s) for obtaining the structural unit derived from an aromatic vinyl compound constituting the principal chain of the copolymer disclosed herein (hereinafter also referred to as a monomer C) can be selected as appropriate from known monomers. Suitable examples include methylstyrenes such as styrene, α-methylstyrene, o-methylstyrene, m-methylstyrene, and p-methylstyrene; and 2,6-dimethylstyrene, 2,4-dimethylstyrene, α-methyl-o-methylstyrene, α-methyl-m-methylstyrene, α-methyl-p-methylstyrene, β-methyl-o-methylstyrene, β-methyl-m-methylstyrene, β-methyl-p-methylstyrene, 2,4,6-trimethylstyrene, α-methyl-2,6-dimethylstyrene, α-methyl-2,4-dimethylstyrene, β-methyl-2,6-dimethylstyrene, β-methyl-2,4-dimethylstyrene, o-t-butylstyrene, m-t-butylstyrene, p-t-butylstyrene, o-methoxystyrene, m-methoxystyrene, p-methoxystyrene, indene, vinylnaphthalene, and N-vinylcarbazole. In view of the manufacturing cost and the physical property balance, styrene, α-methylstyrene, p-methylstyrene, and mixtures thereof are preferred, and styrene is more preferred.

As the copolymer disclosed herein, another monomer(s) that can be copolymerized with the aforementioned monomers A and B (hereinafter also referred to as a monomer D) may be used in the scope in which it is not deviated from the purport of the present disclosure. In order to maintain the satisfactory dielectric characteristic and the satisfactory crack resistance after a heat cycle test, the alicyclic structure, which becomes the principal chain skeleton, preferably contains no heterocycle. Examples of the monomer D include N-vinylcarbazole, aromatic vinyl compounds such as vinylnaphthalene and vinylanthracene, β-pinene, 8,9-p-menene, and dipentene.

The copolymer disclosed herein may be a random copolymer, a block copolymer, or a gradient copolymer, but is preferably a block copolymer in order to achieve both the heat resistance and the stress relaxation. Suitable examples for achieving both the heat resistance and the stress relaxation include copolymers having a block consisting of a structural unit derived from an aromatic vinyl compound and a block containing a structural unit derived from a conjugated diene compound. In order to achieve both the heat resistance and the stress relaxation, more preferably, the block copolymer includes a structural unit derived from an aromatic vinyl compound at both ends of a block containing a structural unit derived from a conjugated diene compound. Further, the principal chain of the copolymer disclosed herein preferably contains a structural unit derived from styrene as a block consisting of a structural unit derived from an aromatic vinyl compound, and contains a structural unit derived from butadiene or isoprene as a block consisting of a structural unit derived from a conjugated diene compound. An A-B-A triblock copolymer and an A-B diblock copolymer are preferred, and an A-B-A triblock copolymer is more preferred. Suitable examples of the block A include a monomer derived from styrene, and suitable examples of the block B include a monomer derived from butadiene or isoprene.

Suitable examples of the copolymer disclosed herein include a hydrogenated styrene-based elastomer, and include a modified form of one of a styrene-ethylene-butylene block copolymer (SEB), a styrene-ethylene-propylene block copolymer (SEP), a styrene-ethylene-butylene-styrene block copolymer (SEBS), a styrene-ethylene-propylene-styrene block copolymer (SEPS), a styrene-ethylene-butylene styrene-styrene block copolymer (SEBSS), a styrene-isobutylene-styrene block copolymer (SIBS), and a styrene-ethylene-ethylene propylene styrene block copolymer (SEEPS).

Any one of the monomers A to D may be used independently, or two or more of these monomers may be used together. In view of the stress relaxation, the sum total of the structural units derived from the monomers A and B constituting the copolymer disclosed herein (including the case where the copolymer contains only one of them) is preferably 30 to 90 mass %, more preferably 40 to 80 mass %, and more preferably 55 to 75 mass % in 100 mass % of the copolymer disclosed herein. In view of the heat resistance, the structural unit derived from monomer C constituting the copolymer disclosed herein is preferably contained in 10 to 70 mass %, more preferably 15 to 60 mass %, still more preferably 20 to 45 mass %, and particularly preferably 25 to 45 mass % in 100 mass % of the copolymer disclosed herein. Further, the sum total of the structural units derived from the monomers A to C constituting the copolymer disclosed herein is preferably 90 mass % or more, more preferably 95 mass % or more, and may be 100 mass % in 100 mass % of the copolymer disclosed herein. Note that the above-shown ranges are ranges in mass % in the olefinic copolymer which has not yet been modified.

### 1-2. Side Group, Side Chain, and Molecular Chain End

The copolymer disclosed herein has a monocyclic structure and/or a polycyclic structure having an alicyclic skeleton (hereinafter also referred to as a non-conjugated C═C bond-containing ring) which satisfies at least one of conditions (i) and (ii) in at least one of a side group, a side chain, and a molecular chain end thereof. In this way, a crosslinking property can be imparted to the copolymer disclosed herein. By crosslinking the copolymer disclosed herein, it is possible to improve the crack resistance after a heat cycle test as well as the heat resistance.

Examples of the monocyclic structure or polycyclic structure having an alicyclic skeleton satisfying the above-described condition (i) include the below-shown Chemical Formula (1).

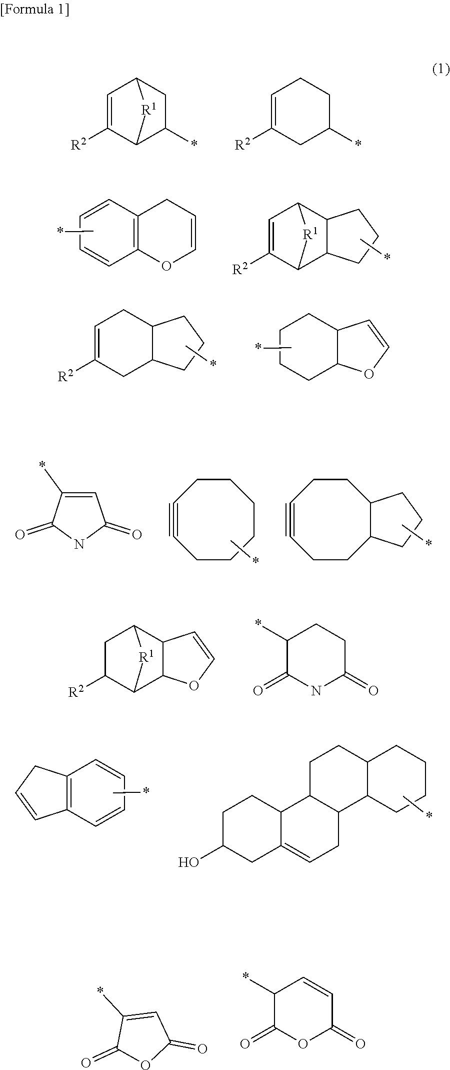

In the formula, R¹ is a direct bond or a methylene group, and R² is a hydrogen or a methyl group. In the formula, * indicates a bonding part with the principal chain or the side chain of the modified olefinic copolymer. The hydrogen atom bonded to the carbon of the ring may be substituted by a substituent. Examples of such substituents include an alkyl group having a carbon number of 1 to 18 (such as a methyl group, an ethyl group, an isopropyl group, and a t-butyl group), an alkoxy group having a carbon number of 1 to 18 (such as a methoxy group, an ethoxy group, and a propoxy group), an aryl group (such as a phenyl group and a naphthyl group), a heteroaromatic group (such as a thienyl group), a haloaryl group (such as a pentafluorophenyl group, a 3-fluorophenyl group, and a 3,4,5-trifluorophenyl group), an alkenyl group such as a vinylidene group, an alkynyl group, an amide group, an acyl group, a haloalkyl group (such as a perfluoroalkyl group), a hydroxy group, a nitro group, a cyano group, a carboxy group, and a halogen group (such as a fluoro group, a chloro group, and a bromo group).

Specific examples of the above-described condition (ii) include groups expressed by the below-shown Chemical Formula (2).

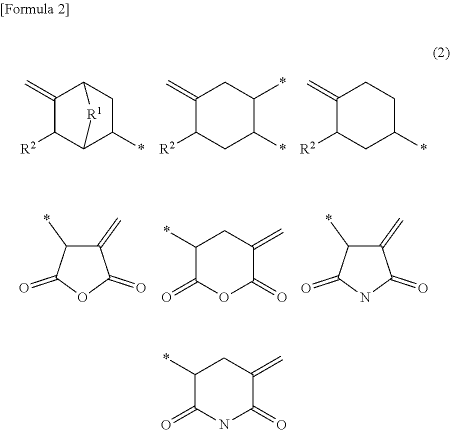

R¹, R², and * in the formula are as described above in Chemical Formula (1). Further, the hydrogen atom bonded to the carbon of the ring may be substituted by a substituent, and suitable examples of such substituents include the substituents shown above in Chemical Formula (1).

In view of the dielectric characteristic, the alicyclic skeleton having a radically reactive non-conjugated carbon-carbon unsaturated bond satisfying at least one of the above-described conditions (i) and (ii) preferably contains no hetero atom such as a maleimide group. In view of the dielectric characteristic, suitable examples of the alicyclic skeleton having a non-conjugated carbon-carbon unsaturated bond include norbornene and terpene (such as alpha-pinene and limonene). When the alicyclic structure contains a norbornene group, no hetero atom is included in the alicyclic structure, so that the dielectric characteristic can be enhanced.

Substantially all the molecular chain ends of the copolymer disclosed herein may have the alicyclic skeleton. Further, some of the molecular chain ends may contain a functional group other than the alicyclic skeleton. Further, some of the molecular chain ends may be closed ends having no functional group. The molecular chain ends of the copolymer disclosed herein may not have the alicyclic skeleton, and may have the alicyclic skeleton in the side chain and/or the side group of the copolymer disclosed herein. It is sufficient if the copolymer disclosed herein has the alicyclic skeleton in at least one of the molecular chain end, the side chain, and the side group.

### 1-3. Copolymerization Type, Weight-Average Molecular Weight, and the Like

The copolymer disclosed herein is preferably a block copolymer in view of the heat resistance and the crack resistance after a heat cycle test. Suitable examples include a block copolymer containing a block consisting of a structural unit derived from an aromatic vinyl compound and a block consisting of a structural unit derived from a conjugated diene compound. Further, a modified block copolymer in which a block containing structural units derived from conjugated diene compounds further contains structural units derived from aromatic vinyl compounds is suitable.

The weight-average molecular weight (hereinafter also referred to as Mw) of the copolymer disclosed herein is not limited to any particular values, but in order to improve the crack resistance after a heat cycle test, the Mw is preferably 20,000 or larger, more preferably 50,000 or larger, and still more preferably 70,000 or larger. In view of the compatibility between the copolymer disclosed herein and a curable compound, the Mw of the copolymer disclosed herein is preferably 400,000 or smaller, more preferably 300,000 or smaller, and still more preferably 200,000 or smaller.

The position of the non-conjugated C═C bond-containing ring of the copolymer disclosed herein may be any of a side group, a side chain, and a molecular chain end thereof, but in view of the manufacturing process, the position is preferably in a side group or a side chain. The amount of the radically reactive non-conjugated carbon-carbon unsaturated bond value of the copolymer disclosed herein is not limited to any particular values, but in order to further improve the heat resistance, the radically reactive non-conjugated carbon-carbon unsaturated bond valence of the conditions (i) and (ii) is preferably 1 to 50 mgKOH/g, more preferably 2 to 35 mgKOH/g, and still more preferably 5 to 25 mgKOH/g.

In view of the heat resistance and the crack resistance after a heat cycle test, the content ratio of the block consisting of a structural unit derived from an aromatic vinyl compound is 10 to 70 mass % in 100 mass % of the copolymer disclosed herein. The content ratio is more preferably 20 to 60 mass %, and still more preferably 25 to 45 mass %.

### 1-4. Manufacturing Method

An example of a method for manufacturing a copolymer according to the present disclosure will be described hereinafter. As a method for manufacturing the copolymer disclosed herein, for example, a resin which has not yet been modified (unmodified copolymer) is obtained by polymerizing monomers containing at least a conjugated diene compound and/or an alicyclic or chain-like non-conjugated olefin compound. The polymerization method may be radical polymerization, anionic polymerization, cationic polymerization, or living polymerization, and a known method can be used. The unmodified block copolymer can be obtained by successively adding monomers. In order to make the principal chain of the unmodified block copolymer include substantially no unsaturated double bonds, a hydrogenation reaction may be carried out by a known method such as a reacting it with pressurized hydrogen in the presence of a catalyst after the polymerization.

The method for introducing (modifying) a non-conjugated C═C bond-containing ring into at least one of a side chain, a side group, and a molecular chain end is preferably a method for manufacturing it through a reaction step of reacting a compound by which a non-conjugated C═C bond-containing ring can be introduced with an unmodified copolymer. Further, a copolymer having a C═C bond-containing ring in a side group may be obtained by partially using a monomer having the non-conjugated C═C bond-containing ring when an olefinic copolymer is polymerized.

The introduction of the non-conjugated C═C bond-containing ring into the molecular chain end can be carried out by polymerizing the unmodified olefinic copolymer, and after that, if necessary, carrying out a hydrogenation reaction, and reacting the compound having the non-conjugated C═C bond-containing ring with it. A compound having a functional group may be introduced into the molecular chain end of the unmodified olefinic copolymer, and a compound having a non-conjugated C═C bond-containing ring may be reacted with the functional group. For example, acrylic acid is introduced into the molecular chain end. After that, a non-conjugated C═C bond-containing ring can be introduced at the molecular chain end by reacting a compound having a monocyclic structure and/or a polycyclic structure having a functional group (such as an amino group, an epoxy group, and a hydroxy groups) which reacts with a carboxy group and having an alicyclic skeleton satisfying at least one of the conditions (i) and (ii) with it.

The introduction of the non-conjugated C═C bond-containing ring into the side chain can be carried out by, for example, a method in which a radical initiator is added to an unmodified olefinic copolymer while heating it and graft-polymerizing an acid anhydride. Examples of compounds by which an acid anhydride group can be introduced include maleic anhydride, citraconic anhydride, and itaconic anhydride. Commercially available products in which these groups are already introduced may be used.

After the acid anhydride is introduced into the unmodified olefinic copolymer, which is a precursor of the copolymer disclosed herein, the copolymer disclosed herein having a non-conjugated C═C bond-containing ring in a side chain thereof can be obtained by reacting all or a part of the acid anhydride with a compound having a monocyclic structure and/or a polycyclic structure having an alicyclic skeleton and satisfying at least one of the conditions (i) and (ii).

Examples of compounds having a monocyclic structure and/or a polycyclic structure having an alicyclic skeleton and satisfying at least one of the conditions (i) and (ii) include the below-shown compounds having a functional group that reacts with carboxylic acid as a substituent. That is, examples include an indene ring having a functional group that reacts with carboxylic acid (such as an amino group, an epoxy group, and a hydroxy group) as a substituent; a cycloalkene ring such as cyclohexene; alkyl substituents such as 5-methyl-bicyclo[2.2.1]hepto-2-ene, 5-ethyl-bicyclo[2.2.1]hepto-2-ene, 5-butyl-bicyclo[2.2.1]hepto-2-ene, 5-hexyl-bicyclo[2.2.1]hepto-2-ene, 5-decyl-bicyclo[2.2.1]hepto-2-ene, 5-cyclohexyl-bicyclo[2.2.1]hepto-2-ene, and 5-cyclopentyl-bicyclo[2.2.1]hepto-2-ene; alkenyl substituents such as 5-ethylidene-bicyclo [2.2.1]hepto-2-ene (5-ethylidene-2 norbornene), 5-vinyl-bicyclo [2.2.1]hepto-2-ene, 5-propenyl-bicyclo [2.2.1]hepto-2-ene, 5-cyclohexenyl-bicyclo [2.2.1]hepto-2-ene, and 5-cyclopentenyl-bicyclo [2.2.1]hepto-2-ene; and rings containing norbornene such as 5-phenyl-bicyclo [2.2.1]hepto-2-ene (5-phenyl-2 norbornene), bicyclo[2.2.1]hepto-2-ene, tricyclo [4.3.0.12,5]deca-3,7-diene, methyldicyclopentadiene, dimethyldicyclopentadiene, tetracyclo [9.2.1.02,10.03, 8]tetradeca-3,5,7,12-tetraene, tetracyclo [10.2.1.02,11.04,9]pentadeca-4,6,8,13-tetraene. Further, examples also include tetracyclododecenes having an unsubstituted or alkyl group such as tetracyclododecene, 8-methyltetracyclododecene, 8-ethyltetracyclododecene, 8-cyclohexyltetracyclododecene, and 8-cyclopentyltetracyclododecene; tetracyclododecenes having a double bond outside the ring such as 8-methylidenetetracyclododecene, 8-ethylidenetracyclododecene, 8-vinyltetracyclododecene, 8-propenyltetracyclododecene, 8-cyclohexenyltetracyclododecene, and 8-cyclopentenyltetracyclododecene; tetracyclododecenes having an aromatic ring such as 8-phenyltetracyclododecene. Further, examples also include tetracyclododecenes having a functional group (such as an amino group, an epoxy group, and a hydroxy group) that reacts with a carboxylic acid, and having a substituent containing an oxygen atom such as 8-methoxycarbonyltetracyclododecene, 8-methyl-8-methoxycarbonyltetracyclododecene, 8-hydroxymethyltetracyclododecene, 8-carboxytetracyclododecene, tetracyclododecene-8,9-dicarboxylic acid, tetracyclododecene-8,9-dicarboxylic acid anhydride.

Examples of the compound having an amino group and a monocyclic structure and/or a polycyclic structure having an alicyclic skeleton, which satisfies at least one of the conditions (i) and (ii), include compounds shown in the below-shown Chemical Formula (3).

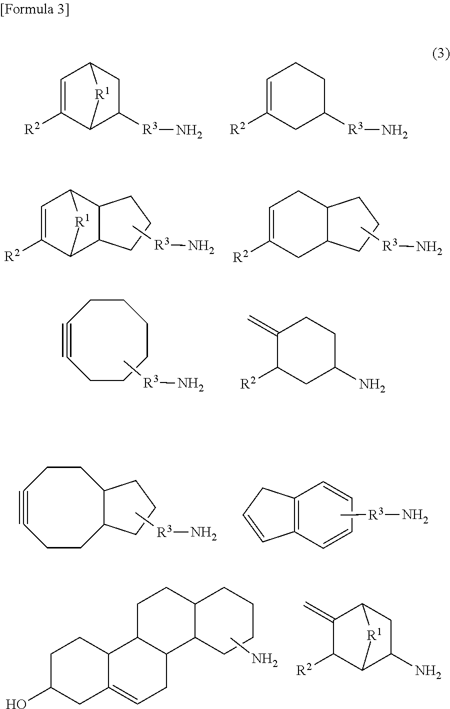

R¹ and R² in the formula are as described above in Chemical Formula (1). R³ is a direct bond or an alkyl group having a carbon number of 1 to 20. R³ is preferably a direct bond or an alkyl group having a carbon number of 1 to 6, and more preferably a direct bond or an alkyl group having a carbon number of 1 to 4. Further, the hydrogen atom bonded to the carbon of the ring may be substituted by a substituent. Examples of such substituents include substituents shown in the description of Chemical Formula (1). A particularly preferred compound is 5-norbornene-2-methylamine.

After the acid anhydride is introduced into the unmodified olefinic copolymer, an imide bond is formed by reacting all or a part of the acid anhydride with a compound having a monocyclic structure and/or a polycyclic structure having an alicyclic skeleton satisfying at least one of the conditions (i) and (ii). This imide bond improves the compatibility with the maleimide compound (b3), which is a curable compound described later, and thereby improves the crosslinking property and improves the heat resistance of the cured article. That is, in view of the heat resistance of the cured article, a resin composition in which an imide bond is introduced into one of the side chain, the side group, and the molecular chain end of the copolymer disclosed herein, and the maleimide compound (b3) is combined as a curable compound is preferred.

The temperature in the reaction for introducing the acid anhydride group into the unmodified olefinic copolymer is preferably 50 to 200° C. and more preferably 100 to 180° C. The temperature in which after the acid anhydride is introduced, the compound having a monocyclic structure and/or a polycyclic structure having an alicyclic skeleton is reacted with the acid anhydride is preferably 80 to 250° C. and more preferably 100 to 200° C.

The time in the reaction for introducing the acid anhydride group into the unmodified olefinic copolymer is preferably 1 to 240 minutes and more preferably 10 to 180 minutes. The time in which after the acid anhydride is introduced, the compound having a monocyclic structure and/or a polycyclic structure having an alicyclic skeleton is reacted with the acid anhydride is preferably 30 to 240 minutes and more preferably 60 to 180 minutes.

It is preferred to add an antioxidant when the acid anhydride group is introduced and the alicyclic skeleton is introduced into the side chain and/or side group. As the antioxidant, for example, known antioxidants can be used. Specific examples of the antioxidant include phenothiazine-based compounds such as phenothiazine, bis-(1-dimethylbenzyl) phenothiazine, and 3,7-dioctylphenothiazine; hindered phenolic compounds such as bis[3-(3-tert-butyl-4-hydroxy-5-methylphenyl)propionic acid][ethylene bis(oxyethylene)]2,4-bis[(laurylthio)methyl]-o-cresol, 1,3,5-tris(3,5-di-t-butyl-4 hydroxybenzyl), 1,3,5-tris(4-t-butyl-3-hydroxy-2,6-dimethylbenzyl), 2,4-bis-(n-octylthio)-6-(4-hydroxy-3,5-di-t-butylanilino)-1,3,5-triazine, and pentaerythritol tetrakis 3-(3,5-di-tert-butyl-4 hydroxyphenyl)propionate; phenoxazine-based compounds such as phenoxazine; nitroso compounds such as 4-nitrosophenol, N-nitrosodiphenylamine, N-nitrosocyclohexylhydroxylamine, and N-nitrosophenylhydroxylamine, or their salts; quinone compounds such as methylhydroquinone, t-butylhydroquinone, 2,5-di-t-butylhydroquinone, and 4-benzoquinone; and phenolic compounds such as 4-methoxyphenol, 4-methoxy-1-naphthol, and t-butylcatechol.

Among them, at least one compound selected from the group consisting of phenothiazine-based compounds, hindered phenolic compounds, and phenoxazine-based compounds is preferred as the antioxidant because the effectiveness of the present disclosure is more improved.

Examples of catalysts include aliphatic tertiary amines such as triethylamine, aromatic tertiary amines such as dimethylaniline, heterocyclic tertiary amines such as pyridine, picoline, and isoquinoline. Further, examples of dehydrating agents include aliphatic anhydrides such as acetic anhydride and aromatic anhydrides such as benzoic anhydride. Suitable examples of radical initiators include compounds described later.

Examples of organic solvents used for the polymerization include N-methyl-2-pyrrolidone (NMP), 2-butanone, dimethyl sulfoxide (DMSO), N,N-dimethylformamide (DMF), N,N-dimethylacetamide (DMAc), N,N-diethylacetamide, hexamethylphosphoramide, N-methylcaprolactam, dimethyl sulfate, cyclohexanone, dioxane, tetrahydrofuran, diglyme, triglyme, and cresol. Only one solvent may be used, or two or more types of solvents may be used in combination. Aromatic hydrocarbons such as xylene and toluene can also be used together.

### 2. Resin Composition

A resin composition according to this embodiment (hereinafter also referred to as the composition disclosed herein) contains at least the copolymer disclosed herein. According to the composition disclosed herein, non-conjugated C═C bond-containing rings between molecules of the copolymer disclosed herein can be cross-linked with each other by a radical initiator. Further, the composition disclosed herein may further contain a curable compound. By containing a curable compound, the non-conjugated C═C bond-containing ring of the copolymer disclosed herein can be cross-linked with the curable compound. By containing a curable compound, it becomes easy to control the crosslinking density of the cured article.

Since the composition disclosed herein has the above-described structure, its cured article has excellent heat resistance. It is considered that the main reason for this is that it is possible to construct a crosslinked structure which starts from a non-conjugated carbon-carbon unsaturated bond of an alicyclic skeleton having relatively mild moderate reactivity or a non-conjugated carbon-carbon unsaturated bond directly connected to an alicyclic skeleton in at least one of a side group, a side chain, and a molecular chain end thereof, and it was possible to suppress the decrease in the mobility of the copolymer disclosed herein after the curing process and improve the stress relaxation property and dispersibility by the relatively flexible and tough chain-like hydrocarbon skeleton in the principal chain. Further, it is considered that by combining the copolymer disclosed herein having a chain-like hydrocarbon skeleton in the principal chain and the radically low reactive “radically reactive non-conjugated carbon-carbon unsaturated bond derived from an alicyclic structure” with the curable compound, a dense contrast with the sparse part of the crosslinked structure is likely to be obtained, so that the heat resistance could be improved. In order to further improve the heat resistance, it is preferred to adopt a saturated hydrocarbon skeleton for the chain-like hydrocarbon skeleton in the principal chain.

Further, since the composition disclosed herein has the above-described structure, a resin composition having an excellent dielectric characteristic can be provided. By using the copolymer disclosed herein having the alicyclic skeleton in at least one of the side group, the side chain, and the molecular chain end thereof, and having the chain-like hydrocarbon skeleton in the principal chain, the steric hindrance is reduced and it is highly reactive because it has the alicyclic skeleton in the side chain and/or side group, so that non-conjugated carbon-carbon unsaturated bond that remains after the curing reaction can be reduced. It is considered that as a result, the generation of a hydroxyl group due to the oxidation and the resultant decrease in the dielectric characteristic can be suppressed, and therefore, the dielectric characteristic is excellent. Each component of the composition disclosed herein and a manufacturing method therefor will be described hereinafter in detail.

### 2-1. Curable Compound

The curable compound refers to a compound that is crosslinked and cured by heating, light irradiation, electron beam irradiation, or the like, and its type is not limited to any particular types. Only one curable compound can be used, or two or more types of curable compounds can used in combination regardless of whether they are the same types or different types.

Suitable examples of the curable compound include an epoxy compound (b1), a cyanate ester compound (b2), a maleimide compound (b3), an allyl group-containing compound (b4), a vinyl group-containing compound (b5), a (meth)acrylate group-containing compound (b6), and a benzoxazine compound (b7) (hereinafter also referred to as components (b1) to (b7)). The curable compound preferably contains at least one component selected from the group consisting of components (b1) to (b7).

The curable compound preferably contains a curable compound (B1) having a radically reactive non-conjugated carbon-carbon unsaturated bond (hereinafter also referred to simply as a curable compound (B1)). The radically reactive non-conjugated carbon-carbon unsaturated bond is a bond that can react with another curable compound and thereby form a crosslinked structure and/or react with the radically reactive non-conjugated carbon-carbon unsaturated bond of the copolymer disclosed herein and thereby form a bond. Suitable examples of the curable compound (Bi) bonded by the radically reactive non-conjugated carbon-carbon unsaturated bond include a maleimide compound (b3), an allyl group-containing compound (b4), a vinyl group-containing compound (b5), and a (meth)acrylate group-containing compound (b6).

In order to further improve the heat resistance, the curable compound preferably contains a maleimide compound (b3). The maleimide compound (b3) may be used alone, or may be used in combination with one or more of the components (b1), (b2), and (b4)-(b7). Suitable combinations include a combination of the cyanate ester compound (b2) and the maleimide compound (b3), or a combination of the maleimide compound (b3) and at least one of the components (b4) to (b7). Among them, a combination of the maleimide compound (b3) and the allyl group-containing compound (b4) is more preferred. Further, particularly preferably, the maleimide compound (b3) and the benzoxazine compound (b7) are thermally reacted and crosslinked, so that the reactivity of the maleimide is improved and the dielectric characteristic is also excellent.

In order to form a stronger crosslink by the reaction between carbon-carbon unsaturated bonds, combinations of the maleimide compound (b3) and the allyl group-containing compound (b4), the maleimide compound (b3) and the vinyl group-containing compound (b5), and the maleimide compound (b3) and the (meth)acrylate group-containing compound (b6) are preferred.

In order to improve the toughness, it is preferred to use a curable compound having a polyphenylene ether structure in the compounds (b1) to (b7). More preferably, in the allyl group-containing compound (b4), the vinyl group-containing compound (b5), the (meth) acrylate group-containing compound (b6), and the benzoxazine compound (b7), it is a polyphenylene ether compound having a structure expressed by the below-shown General Formula (4) in a part of the structure.

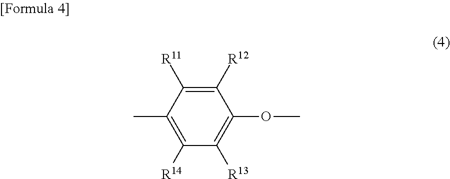

Examples of R¹¹, R¹², R¹³ and R¹⁴ include, for each repeating unit and independently, a hydrogen atom, a halogen atom (such as a fluorine atom, a chlorine atom, a bromine atom), an alkyl group which may have a substituent (a linear or branched alkyl group having a carbon number of 1 to 6, such as a methyl group, an ethyl group, a propyl group, an isopropyl group, a butyl group, an isobutyl group, a tert-butyl group, a pentyl group, and a heptyl group, and cycloalkyl group such as a cyclohexyl group), an alkoxy group which may have a substituent (an alkoxy group having a carbon number of 1 to 6, such as a methoxy group, an ethoxy group, a butoxy group, and a propoxy group), an aryl group which may have a substituent (such as a phenyl group and a naphthyl group), and an amino group which may have a substituent, a carboxy group, a nitro group, and a cyano group.

In view of the heat resistance, especially the long-term heat resistance, the average number of curable functional groups of the polyphenylene ether compound is preferably 1 to 10, and more preferably 2 or larger.

The Mw of the components (b4) to (b7) having the polyphenylene ether structure is not limited to any particular values, but in order to improve the crack resistance after a heat cycle test, it is preferably 200 or larger, and more preferably 500 or larger. The upper limit of Mw is not limited to any particular values, but it is 10,000 or smaller in consideration of availability and the like.

It is preferred to use the curable compound in 10 to 98 mass %, more preferably 30 to 90 mass %, and still more preferably 45 to 85 mass % in the 100 mass % of the components other than the filler and the solvent in the composition disclosed herein.

In view of the heat resistance, it is preferred that the molecular weight of the curable compound be 100 or larger and smaller than 10,000, and it contain a curable compound (B1) having a radically reactive non-conjugated carbon-carbon unsaturated bond. Further, in addition to the above-described aspect, the heat resistance can be improved by adjusting the content ratio of the copolymer disclosed herein to 5 to 40 mass % based on the total of 100 mass % of the copolymer disclosed herein and the curable compound (B1).

Note that the molecular weight of the curable compound is the molecular weight in the case of a low-molecular compound, and is the number average molecular weight in the case of a compound obtained by polymerizing monomers. When two or more types of curable compounds are used, the molecular weight of the curable compound is the sum total of the molecular weights of all the curable compounds each of which is obtained by the molecular weight of that curable compound x the content ratio (mass %) of the curable compound.

The epoxy compound (b1) is a curable compound containing an epoxy group. The epoxy compound (b1) is preferably used in combination with an active ester compound. The active ester compound is a compound having, in one molecule, at least one ester group that reacts with an epoxy group, and thereby hardens an epoxy resin. Examples of commercially available active ester compounds include “HPC-8000-65T”, “EXB 9416-70BK” and “EXB 8100-65T” manufactured by DIC Corporation.

By using the active ester compound, an ester group is generated by the reaction of the epoxy compound (b1) and the active ester compound. Therefore, the polarity can be reduced compared to the case where a phenolic curing agent is used. As a result, the dielectric characteristic can be improved more effectively.

Specific examples of the epoxy compound (b1) include a glycidyl ether-type epoxy resins; tetraglycidyl diaminodiphenylmethane, triglycidyl paraaminophenol, triglycidyl meta-aminophenol, or glycidyl amine-type epoxy resins such as tetraglycidyl methaxylylenediamine and sorbitol polyglycidyl ether; glycidyl ester-type epoxy resins such as diglycidyl phthalate, diglycidyl hexahydrophthalate, or diglycidyl tetrahydrophthalate; cyclic aliphatic (alicyclic) epoxy resins such as epoxycyclohexyl methyl-epoxycyclohexane carboxylate or bis(epoxycyclohexyl) adipate; bisphenol A-type epoxy resins, bisphenol F-type epoxy resins, bisphenol S-type epoxy resins, and bisphenol AD-type epoxy resins. Further, examples also include cresol novolak-type epoxy resins, phenol novolak-type epoxy resins, α-naphthol novolak-type epoxy resins, bisphenol A-type novolak-type epoxy resins, dicyclopentadiene epoxy resins, tetrabrombisphenol A-type epoxy resins, and brominated phenol novolak-type epoxy resins.

The cyanate ester compound (b2) refers to a curable resin having a cyanate group. Examples of the cyanate ester compound (b2) include bisphenol A-type cyanate ester resina, bisphenol A-type cyanate ester resins, bisphenol F-type cyanate ester resins, bisphenol E-type cyanate ester resins, bisphenol S-type cyanate ester resins, bisphenol sulfide-type cyanate ester resins, phenylene ether-type cyanate ester resins, naphthylene ether-type cyanate ester resins, biphenyl-type cyanate ester resins, tetramethylbiphenyl-type cyanate ester resins, polyhydroxynaphthalene-type cyanate ester resins, phenol novolac-type cyanate ester resins, cresol novolac-type cyanate ester resins, triphenylmethane-type cyanate ester resins, tetraphenylethane-type cyanate ester resins, dicyclopentadiene-phenol addition reaction-type cyanate ester resins, phenol aralkyl-type cyanate ester resins, Examples include naphthol-novolak-type cyanate ester resins, naphthol-aralkyl-type cyanate ester resins, naphthol-phenol co-condensed novolak-type cyanate ester resins, naphthol-cresol co-condensed novolak-type cyanate ester resins, aromatic hydrocarbon formaldehyde resin-modified phenolic resin-type cyanate ester resins, biphenyl-modified novolak-type cyanate ester resins, and anthracene-type cyanate ester resins.

Commercially available cyanate ester compounds (b2), such as a phenol novolak-type cyanate ester resin (PT-30 and PT-60 manufactured by Lonza Japan) and prepolymers containing a trimerized bisphenol-type cyanate ester resin (BA-230S, BA-3000S, BTP-1000S and BTP-6020S manufactured by Lonza Japan) may be used.

In order to improve the heat resistance and the crack resistance after a heat cycle test, it is preferred to include a maleimide compound (b3) having a molecular weight of 100 or larger and smaller than 10,000. It is considered that by combining such a reactive maleimide compound (b3) having a relatively small molecular weight with the copolymer disclosed herein which has a relatively large molecular weight, is relatively low reactive, and is bonded by a radically reactive non-conjugated carbon-carbon unsaturated bond derived from an alicyclic structure, a sparse part and a dense part of the crosslinked structure are likely to be formed, so that the heat resistance and the crack resistance after a heat cycle test can be effectively improved.

Examples of the maleimide compounds (b3) include polyfunctional maleimides obtained by reacting polyfunctional amines with maleic anhydride. Examples of polyfunctional amines include isophorondiamine, dicyclohexylmethane-4,4′-diamine, JEFFAMINE D-230, HK-511, D-400, XTJ-582, D-2000, XTJ-578, XTJ-509, XTJ-510, T-403, and T-5000 each having a terminal aminated polypropylene glycol skeleton; XTJ-500, XTJ-501, XTJ-502, XTJ-504, XTJ-511, XTJ-512, and XTJ-590 each having a terminal aminated ethylene glycol skeleton; and XTJ-542, XTJ-533, XTJ-536, XTJ-548, and XTJ-559 each having a terminal aminated polytetramethylene glycol skeleton.

Examples of the maleimide compound (b3) include resins having two maleimide groups in a molecule, such as 4,4′-diphenylmethane bismaleimide, m-phenylenebismaleimide, p-phenylenebismaleimide, 2,2-bis [4-(4-maleimidophenoxy) phenyl]propane, bis-(3-ethyl-5-methyl-4-maleimidophenyl) methane, 4-methyl-1,3-phenylenebismaleimide, N,N′-ethylene dimaleimide, N,N′-hexamethylene dimaleimide, bis(4-maleimidophenyl)ether, bis(4-maleimidophenyl) sulfone, 3, 3′-dimethyl-5, 5′-diethyl-4,4′-diphenylmethane bismaleimide, and bisphenol A diphenyl ether bismaleimide; biphenylaralkyl-type maleimide, polyphenylmethane maleimide (CASNO: 67784-74-1, a reactant of a polymer consisting of formaldehyde and aniline, and maleic anhydride), N,N′-(toluene-2,6-diyl)bismaleimide), 4,4′-diphenyl ether bismaleimide, 4,4′-diphenylsulfone bismaleimide, 1,3-bis(3-maleimidophenoxy)benzene, 1,3-bis(4-maleimidophenoxy)benzene, N,N′-ethylene bismaleimide, N,N′-trimethylene bismaleimide, N,N′-propylene bismaleimide, N,N′-tetramethylene bismaleimide, N,N′-pentamethylene bismaleimide, N,N′-(1,3-pentanediyl)bis(maleimide), N,N′-hexamethylene bismaleimide, N,N′-(1,7-heptanediyl)bismaleimide, N,N′-(1,8-octanediyl)bismaleimide, N,N′-(1,9-notanediyl)bismaleimide, N,N′-(1,10-decanediyl)bismaleimide, N,N′-(1,11-undecanediyl)bismaleimide, N,N′-(1,12-dodecanediyl)bismaleimide, N,N′-[(1,4-phenylene)bismethylene]bismaleimide, N,N′-[(1,2-phenylene)bismethylene]bismaleimide, N,N′-[(1,3-phenylene)bismethylene]bismaleimide, 1,6′-bismaleimido-(2,2,4-trimethyl)hexane, N,N′-[(methylimino)bis(4,1-phenylene)]bismaleimide, N,N′-(2-hydroxypropane-1,3-diylbisiminobiscarbonylbisethylene)bismaleimide, N,N′-(dithiobisethylene)bismaleimide, N,N′-[hexamethylenebis(iminocarbonylmethylene)]bismaleimide, N,N′-carbonylbis(1,4-phenylene)bismaleimide, N,N′,N″-[nitrilotris (ethylene)]trismaleimide, N,N′,N″-[nitrilotris (4,1-phenylene)]trismaleimide, N,N′-[p-phenylenebis(oxy-p-phenylene)]bismaleimide, N,N′-[methylenebis(oxy)bis(2-methyl-1,4-phenylene)]bismaleimide, N,N′-[methylenebis(oxy-p-phenylene)]bis(maleimide), N,N′-[dimethylsilylenebis [(4,1-phenylene)(1,3,4,-oxadiazole-5,2-diyl)(4,1-phenylene)]]bismaleimide, N,N′-[(1,3-phenylene)bisoxybis(3,1-phenylene)]bismaleimide, 1,1′-[3′-oxospiro [9H-xanthene-9,1′ (3′H)-isobenzofuran]-3,6-diyl]bis(1H-pyrrole-2,5-dione), N,N′-(3,3′-dichlorobiphenyl-4,4′-diyl) bismaleimide, N,N′-(3,3′-dimethylbiphenyl-4,4′-diyl) bismaleimide, N,N′-(3,3′-dimethoxybiphenyl-4,4′-diyl) bismaleimide, N,N′-[methylenebis(2-ethyl-4,1-phenylene)]bismaleimide, N,N′-[methylenebis(2,6-diethyl-4,1-phenylene)]bismaleimide, N,N′-[methylenebis(2-bromo-6-ethyl-4,1-phenylene)]bismaleimide, N,N′-[methylenebis(2-methyl-4,1-phenylene)]bismaleimide, N,N′-[ethylenebis(oxyethylene)]bismaleimide, N,N′-[sulfonylbis(4,1-phenylene) bis(oxy) bis(4,1-phenylene)]bismaleimide, N,N′-[naphthalene-2,7-diylbis(oxy) bis(4,1-phenylene)]bismaleimide, N,N′-[p-phenylene bis(oxy-p-phenylene)]bismaleimide, N,N′-[(1, 3-phenylene) bisoxybis(3,1-phenylene)]bismaleimide, N,N′-(3,6,9-trioxaundecane-1,-11-diyl) bismaleimide, N,N′-[isopropylidenebis [p-phenyleneoxycarbonyl (m-phenylene)]]bismaleimide, N,N′-[isopropylidenebis [p-phenyleneoxycarbonyl (p-phenylene)]]bismaleimide, N,N′-[isopropylidenebis [(2,6-dichlorobenzene-4,1-diyl) oxycarbonyl (p-phenylene)]]bismaleimide, N,N′-[(phenylimino) bis(4,1-phenylene)]bismaleimide, N,N′-[azobis(4,1-phenylene)]bismaleimide, N,N′-[1,3,4-oxadiazole-2,5-diylbis(4,1-phenylene)]bismaleimide, 2,6-bis [4-(maleimide-N-yl) phenoxy]benzonitrile, N,N′-[1,3,4-oxadiazole-2,5-diylbis(3,1-phenylene)]bismaleimide, N,N′-[nis [9-oxo-9H-9-phospha (V)-10-oxaphenanthrene-9-yl]methylenebis(p-phenylene)]bismaleimide, N,N′-[hexafluoroisopropylidenebis [p-phenyleneoxycarbonyl (m-phenylene)]]bismaleimide, N,N′-[carbonylbis [(4,1-phenylene) thio(4,1-phenylene)]]bismaleimide, N,N′-carbonylbis(p-phenyleneoxy-p-phenylene) bismaleimide, N,N′-[5 tert-butyl-1,3-phenylene bis [(1,3, 4-oxadiazole-5,2-diyl) (4,1-phenylene)]]bismaleimide, N,N′-[cyclohexylidenebis(4,1 phenylene)]bismaleimide, N,N′-[methylenebis(oxy) bis(2-methyl-1,4-phenylene)]bismaleimide, N,N′-[5-[2-[5-(dimethylamino)-1-naphthylsulfonylamino]ethylcarbamoyl]-1,3-phenylene]bismaleimide, N,N′-(oxybisethylene) bismaleimide, N,N′-[dithiobis(m-phenylene)]bismaleimide, N,N′-(3,6, 9 trioxaundecane-1, -11-diyl) bismaleimide, N,N′-(ethylene bis-p-phenylene) bismaleimide, polyfunctional maleimides such as BMI-689, BMI-1500, BMI-1700, BMI-3000, BMI-5000, and BMI-9000 manufactured by DesignerMolecules, and ODA-BMI and BAFBMI manufactured by JFE Chemical Corporation.

When the maleimide compound (b3) is crosslinked by a radical, a radical polymerization initiator may be added. Examples include azo-based compounds and organic peroxides. Only one polymerization initiator may be used, or two or more-types of polymerization initiators may be used in combination.

Examples of azo-based compounds include 2,2′-azobisisobutyronitrile, 2,2′-azobis(2-methylbutyronitrile), 1,1′-azobis(cyclohexane 1-carbonitrile), 2,2′-azobis(2,4-dimethylvaleronitrile), 2,2′-azobis(2,4-dimethyl-4-methoxyvaleronitrile), dimethyl 2,2′-azobis(2-methylpropionate), 4,4′-azobis(4-cyanovaleric acid), 2,2′-azobis(2-hydroxymethylpropionitrile), and 2,2′-azobis [2-(2-imidazoline-2 yl)propane].

Examples of organic peroxides include benzoyl peroxide, t-butyl perbenzoate, cumene hydroperoxide, diisopropyl peroxydicarbonate, di-n-propyl peroxydicarbonate, di(2-ethoxyethyl)peroxydicarbonate, t-butyl peroxy 2-ethylhexanoate, t-butyl peroxyneodecanoate, t-butyl peroxybivalate, (3,5,5-trimethylhexanoyl)peroxide, dipropionyl peroxide, and diacetyl peroxide.

The allyl group-containing compound (b4) may be monofunctional or polyfunctional. Examples of monofunctional allyl compounds include (meth)allyl alcohol. Examples of polyfunctional allyl compounds include triallyl isocyanurate, trimethylolpropane diallyl ether, trimethylolpropane triallyl ether, pentaerythritol diallyl ether, pentaerythritol triallyl ether, tetraallyloxyethane, polyallyl saccharose, di(meth)allylphthalate, tri(meth)allyl isocyanurate, and tri(meth)allyl cyanurate. Further, examples also include the below-shown compounds.

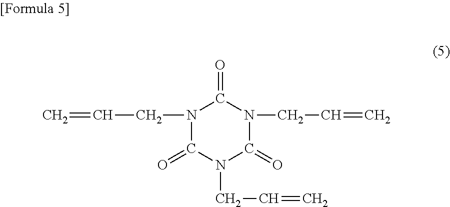 [SMILES: C=CCn1c(=O)n(CC=C)c(=O)n(CC=C)c1=O]

The vinyl group-containing compound (b5) may be monofunctional or polyfunctional. Examples of monofunctional vinyl compounds include styrene, vinyl toluene, N-vinyl pyrrolidone, N-vinyl caprolactam, vinyl imidazole, and vinyl pyridine. Examples of polyfunctional vinyl compounds include hexanediol dinorbornene carboxylate, vinyl benzyl-modified polyphenylene ether, pentaerythritol tetranorbornene carboxylate, triethylene glycol divinyl ether, cyclohexanedimethanol divinyl ether, vinyl ethers such as cyclohexanediol divinyl ether, and divinylbenzene. Among them, vinyl group-containing polyphenylene ether is particularly preferred.

The (meth)acrylate group-containing compound (b6) may be monofunctional or polyfunctional. Examples include monofunctional (meth)acrylamide compounds, polyfunctional (meth)acrylamide compounds, monofunctional (meth)acrylates, and polyfunctional (meth)acrylates.

Examples of monofunctional (meth)acrylamide compounds include diacetone (meth)acrylamide, isobutoxymethyl (meth)acrylamide, N,N-dimethyl (meth)acrylamide, t-octyl (meth)acrylamide, N,N-diethyl (meth)acrylamide, N,N-dimethylaminopropyl (meth)acrylamide, (meth)acryloylmorpholine, acrylamide-2 methylpropanesulfonic acid, and N-isopropyl (meth)acrylamide.

Examples of polyfunctional (meth)acrylamide compounds include N,N′-diacryloyl-4,7,10-trioxa-1,13-tridecanediamine, N,N′,N″-triacryloyl diethylenetriamine, N,N′,N″,N′″-tetraacryloyl triethylenetetramine, and N,N′-{[2-Acrylamide-2-[(3-acrylamidopropoxy)methyl]propane-1,3-diyl)bis(oxy)]bis(propane-1,3-diyl)}diacrylamide.

Examples of monofunctional (meth)acrylates include methyl (meth)acrylate, ethyl (meth)acrylate, propyl (meth)acrylate, isopropyl (meth)acrylate, butyl (meth)acrylate, isobutyl (meth)acrylate, 2-ethylhexyl (meth)acrylate, octyl (meth)acrylate, isooctyl (meth)acrylate, lauryl (meth)acrylate, stearyl (meth)acrylate, cyclohexyl (meth)acrylate, isobornyl (meth)acrylate, cyclopentanyl (meth)acrylate, dicyclopentenyl (meth)acrylate, dicyclopentenyloxyethyl (meth)acrylate, benzyl (meth)acrylate, (meth)acrylate of phenol alkylene oxide adduct, (meth)acrylate of p-cumyl phenol alkylene oxide adduct, (meth)acrylate of o-phenylphenol alkylene oxide adduct, (meth)acrylate of nonylphenol alkylene oxide adduct, 2-methoxyethyl (meth)acrylate, ethoxyethoxyethyl (meth)acrylate, (meth)acrylate of 2-ethylhexyl alcohol alkylene oxide adduct, tetrahydrofurfuryl (meth)acrylate, caprolactone-modified tetrahydrofurfuryl (meth)acrylate, (2-ethyl-2-methyl-1,3-dioxolane-4-yl)methyl (meth)acrylate, (2-isobutyl-2-methyl-1,3-dioxolane-4-yl)methyl (meth)acrylate, (1,4 dioxaspiro [4,5]decane-2-yl)methyl (meth)acrylate, glycidyl (meth)acrylate, 3,4 epoxycyclohexylmethyl (meth)acrylate, (3-ethyloxetane-3-yl)methyl (meth)acrylate, 2-(meth)acryloyloxyethyl isocyanate, allyl (meth)acrylate, N-(meth)acryloyloxyethyl hexahydrophthalimide, N-(meth)acryloyloxyethyl tetrahydrophthalimide, 2-(meth)acryloyloxyethyl hexahydrophthalic acid, 2-(meth)acryloyloxyethyl succinic acid, (o-carboxy-polycaprolactone mono (meth)acrylate, 2-(meth)acryloyloxyethyl acid phosphate, 3-(meth)acryloyloxypropyltrimethoxysilane, 3-(meth)acryloyloxypropyldimethoxymethylsilane, 3-(meth)acryloyloxypropyltriethoxysilane, 2-(Meth)acryloyloxyethyl acid phosphate.

Examples of the alkylene oxide in the alkylene oxide adduct include ethylene oxide and propylene oxide.

Examples of polyfunctional (meth)acrylates include: di(meth)acrylates of aliphatic diols such as methacrylate group-containing polyphenylene ether, ethylene glycol di(meth)acrylate, propylene glycol di(meth)acrylate, 1,4-butanediol di(meth)acrylate, neopentyl glycol di(meth)acrylate, 1,6-hexanediol di(meth)acrylate, 3-methyl-1,5-pentanediol di(meth)acrylate, 2 butyl-2-ethyl-1,3 propanediol di(meth)acrylate, and 1,9 nonanediol di(meth)acrylate; di(meth)acrylates of alicyclic diols such as cyclohexane dimethylol di(meth)acrylate, and tricyclodecane dimethylol di(meth)acrylate; alkylene glycol (meth)acrylates such as diethylene glycol di(meth)acrylate, dipropylene glycol (meth)acrylate, triethylene glycol (meth)acrylate, and tripropylene glycol (meth)acrylate; esterification reaction products of neopentyl glycol, hydroxypivalic acid, and (meth)acrylic acid (hereinafter referred to as “hydroxypivalic acid neopentyl glycol (meth)acrylate”), and caprolactone-modified neopentyl glycol (meth)acrylate; di(meth)acrylates of alkylene oxide adducts of bisphenol-based compounds such as bisphenol A alkylene oxide adducts; di(meth)acrylates of hydrogenated bisphenol-based compounds such as hydrogenated bisphenol A di(meth)acrylates; di(meth)acrylates of isocyanuric acid alkylene oxide adducts, tri (meth)acrylates of isocyanuric acid alkylene oxide adducts, di(meth)acrylates of caprolactone-modified isocyanuric acid alkylene oxide adducts, poly (meth)acrylates of isocyanuric acid alkylene oxide adducts such as caprolactone-modified isocyanuric acid alkylene oxide adducts; polyol poly (meth)acrylates such as trimethylolpropane tri (meth)acrylate, ditrimethylolpropane tetra (meth)acrylate, pentaerythritol tri or tetra (meth)acrylate, and dipentaerythritol penta or hexa (meth)acrylate; poly (meth)acrylates of polyol alkylene oxide adducts, such as tri (meth)acrylate of trimethylolpropane alkylene oxide adducts, tetra (meth)acrylate of ditrimethylolpropane alkylene oxide adducts, tri or tetra (meth)acrylate of pentaerythritol alkylene oxide adducts, and penta or hexa (meth)acrylate of dipentaerythritol alkylene oxide adducts: urethane (meth)acrylate; epoxy (meth)acrylate; and polyester (meth)acrylate.

Examples of the alkylene oxide in the alkylene oxide adduct include ethylene oxide and propylene oxide.

Examples of the benzoxazine compound (b7) include compounds having a benzoxazine skeleton, specifically, o-cresol aniline-type benzoxazine resins, m-cresol aniline-type benzoxazine resins, p-cresol aniline-type benzoxazine resins, phenol-aniline-type benzoxazine resins, phenol-methylamine-type benzoxazine resins, phenol-cyclohexylamine-type benzoxazine resins, phenol-m-toluidine-type benzoxazine resins, phenol-3,5-dimethylaniline-type benzoxazine resins, bisphenol A-aniline-type benzoxazine resins, bisphenol A-amine-type benzoxazine resins, bisphenol F-aniline-type benzoxazine resins, bisphenol S-aniline-type benzoxazine resins, dihydroxydiphenylsulfone-aniline-type benzoxazine resins, dihydroxydiphenyl ether-aniline-type benzoxazine resins, benzophenone-type benzoxazine resins, biphenyl-type benzoxazine resins, bisphenol AF-aniline-type benzoxazine resins, bisphenol A-methylaniline-type benzoxazine resins, phenol-diaminodiphenylmethane-type benzoxazine resins, triphenylmethane-type benzoxazine resins, and phenolphthalein-type benzoxazine resins.

A phenol resin or an isocyanate group-containing compound may be used as a curable compound other than components (b1) to (b7).

### 2-2. Other Components

The composition disclosed herein may contain other compounds in the scope in which it is not deviated from the purport of the present disclosure. For example, a copolymer that does not fall in the copolymer disclosed herein may be used. Further, an arbitrary thermoplastic resin may be used. A radical polymerization initiator may be added in order to accelerate the crosslinking reaction of the radically reactive non-conjugated carbon-carbon unsaturated bond. Further, the curing process can be efficiently accelerated by using a catalyst. Suitable examples of such catalysts include imidazole-based catalysts, amine-based catalysts, and phosphorus-based catalysts.

Known compounds can be used as the radical polymerization initiator. Examples include peroxides such as benzoyl peroxide, cumene hydroperoxide, 2,5-dimethylhexane-2,5-dihydroperoxide, 2,5-dimethyl-2,5-di(t-butylperoxy)hexine-3, di-t-butyl peroxide, t-butyl cumyl peroxide, α,α′-bis(t-butylperoxy-m-isopropyl)benzene, 2,5-dimethyl-2,5-di(t-butylperoxy)hexane, dicumyl peroxide, di-t-butylperoxyisophthalate, t-butylperoxybenzoate, 2,2-bis(t-butylperoxy)butane, 2,2-bis(t-butylperoxy)octane, di-t-amylperoxide, 2,5-dimethyl-2,5-di(benzoylperoxy)hexane, di(trimethylsilyl)peroxide, trimethylsilyltriphenylsilyl peroxide, and diisopropylbenzene hydroperoxide. Further, 2,3-dimethyl-2,3-diphenylbutane is also suitable as the radical polymerization initiator.

The amount of the radical polymerization initiator to be mixed is in a range of 0.01 to 10 pts·mass, preferably 0.1 to 8 pts·mass based on 100 pts·mass of the copolymer disclosed herein. In this range, the reaction satisfactorily proceeds without inhibiting the curing reaction.

Further, examples include inorganic fillers, heat stabilizers, dyes, pigments (e.g., carbon black), polymerization inhibitors, antifoaming agents, leveling agents, ion collectors, moisturizers, viscosity adjusters, antiseptics, antibacterial agents, antistatic agents, antiblocking agents, ultraviolet absorbers, infrared absorbers, and electromagnetic-wave shielding agents.

The composition disclosed herein may contain no solvent or may contain a solvent(s). Examples of solvents include toluene, xylene, methyl ethyl ketone, N,N-dimethylformamide, methyl isobutyl ketone, N-methyl pyrrolidone, acetone, methanol, ethanol, butanol, 2-propanol, 2-methoxyethanol, 2-ethoxyethanol, 1-methoxy-2-propanol, 2-acetoxy-1 methoxypropane, n-hexane, cyclohexane, cyclohexanone, and mixtures thereof.

It is preferred to use a fluorine-based filler in order to lower the dielectric constant more effectively. Examples of fluorine-based fillers include PTFE, PVDF (a vinylidene fluoride polymer having a straight-chain structure in which CF₂ and CH₂ are alternately bonded), neoflon FEP (tetrafluoroethylene-hexafluoropropylene copolymer: tetrafluoroethylene-hexafluoropropylene copolymer resin), PFA (tetrafluoroethylene-perfluoroalkyl vinyl ether copolymer: perfluoroalkoxy resin), neoflon ETFE (copolymer of tetrafluoroethylene and ethylene), and ECTFE (polychlorotrifluoroethylene: trifluoroethylene chloride resin).

The type of inorganic fillers is not limited to any particular types. By using an inorganic filler, the crack resistance after a heat cycle test is more improved.

Specific examples of inorganic fillers include metal compounds such as alumina, aluminum hydroxide, zirconium hydroxide, barium hydroxide, calcium hydroxide, magnesium hydroxide, calcium carbonate, magnesium carbonate, zinc carbonate, barium carbonate, magnesium sulfate, titanium oxide, tin oxide, magnesium oxide, zirconium oxide, calcium oxide, zinc oxide, molybdenum oxide, antimony oxide, nickel oxide, calcium silicate, beryllia, calcium titanate, silicon carbide, silicon nitride, aluminum nitride, boron nitride, titanium white, zinc borate, and aluminum borate; talc; clay; mica; metal oxides and metal nitrides such as glass fibers, kaolin, hydrotalcite, wollastonite, zonotolite, calcium hydrogen phosphate, calcium phosphate, glass flakes, hydrated glass and sepiolite; hydrated metal compounds; silica-based fillers such as fused fractured silica, fused spherical silica, crystalline silica, non-crystalline silica, secondary aggregated silica, fine powdered silica, hollow silica, and porous silica; nitrogen-based and carbon-based fillers such as silicon carbide, silicon nitride, titanium carbide, and diamond.

Among them, silica-based fillers, alumina, aluminum nitride, and boron nitride are more preferred, and silica-based fillers, alumina, and boron nitride are particularly preferred in order to effectively improve the crack resistance.

### 2-3. Characteristics of Resin Composition and Cured Article

A cured article is obtained by curing the composition disclosed herein. Note that the cured article refers to forming a three-dimensional crosslinked structure and thereby curing by a curing process, and refers to a state in which the cured article has been cured to such an extent that the curing reaction does not substantially advance any longer even when a curing process is carried out again. By the curing process, there are a state in which curable compounds crosslink each other, a state in which a curable compound crosslinks with the copolymer disclosed herein, a state in which a curable compound crosslinks with other components, and any combination of these states. The curing process is performed by a radical reaction or the like. If necessary, heating is performed. Note that when the composition disclosed herein is molded into a desired shape such as a sheet, a part of the composition disclosed herein can undergo a curing reaction, but the state in which it can be cured by an additional curing process is not included in the cured article herein. At the stage of the resin composition, it may be in a B-stage in which a part of the component is semi-cured.

### 3. Method for Manufacturing Resin Composition

The composition disclosed herein is obtained by mixing components to be mixed. In the mixing, a solvent(s) can be used as appropriate. The solid content concentration is, for example, 20 to 60 mass %. The composition disclosed herein is in the form of, for example, a powder, a film, a sheet, a plate, pellets, paste, or liquid. The resin composition in the form of liquid or paste can be easily obtained by adjusting the viscosity by using a solvent. Further, the resin composition in the form of a film, a sheet, or a plate can be formed by, for example, applying and drying the resin composition in the form of liquid or paste. Further, the resin composition in the form of a powder or pellets can be obtained by, for example, grinding or dividing the above-described resin composition in the form of a film or the like into desired sizes.

### 4. Resin Composition Layer, Laminated Sheet, and Prepreg

The composition disclosed herein can be suitably used as a resin composition layer. Further, the composition disclosed herein can be suitably used for a laminated sheet including a base material and a resin composition layer formed of the composition disclosed herein provided on the base material. Since the resin composition layer exhibits excellent adhesiveness after the curing process, it is suitably used for bonding various materials (such as a resin layer, a metal layer, an inorganic layer such as ITO, and a composite layer). For example, it is suitably used as an adhesive sheet for a copper clad laminate (CCL: Copper Clad Laminate) and as a bonding material between an electronic circuit board and electronic components and the like.

For example, a laminated sheet having a resin composition layer (adhesive sheet) can be obtained by applying a coating liquid (varnish) of the composition disclosed herein containing a solvent to one surface of a release film and removing and drying a liquid medium such as an organic solvent at 40 to 150° C. A laminated sheet, which is an adhesive sheet with release films on both surfaces, can be obtained by laminating another release film on a surface of the obtained adhesive sheet. By laminating release films on both surfaces, the contamination on the surfaces of the adhesive sheet can be prevented. The adhesive sheet can be separated by peeling the release films. The two release films can be of the same-type or different-types. By using release films having different release properties, it is possible to change the release forces from each other, and thereby make it easier to release them one by one. Further, a laminated sheet having an adhesive sheet (resin composition layer) may be obtained by applying a coating liquid to a base material other than the release-type base material.

Examples of the base material include resin materials such as a polyimide film, a polyethylene film, polycarbonate, polyethylene, a liquid crystal polymer, a phenolic resin, and an aramid resin; metal materials such as copper, aluminum, and stainless steel; inorganic materials such as ITO, glass, silicon, and silicon carbide; and composite materials obtained by arbitrarily combining these materials. According to the composition disclosed herein, by using the copolymer disclosed herein having the alicyclic structure in at least one of a side chain, a side group, or a molecular chain end thereof and having a non-conjugated C═C bond-containing ring, the composition disclosed herein has not only excellent heat resistance to various base materials but also excellent moldability.

As for the coating method, known methods such as comma coat, knife coat, die coat, lip coat, roll coat, curtain coat, bar coat, gravure printing, flexo printing, screen printing, dip coat, spray coat, and spin coat can be selected. The thickness of the adhesive sheet after being dried is preferably 5 to 500 μm and more preferably 10 to 100 μm in order to achieve sufficient adhesiveness and in view of the ease of handling.

The composition disclosed herein can be suitably used as a material for forming a prepreg which is obtained by impregnating a base material with the composition disclosed herein. The prepreg can be manufactured, for example, by impregnating a fibrous base material with the composition disclosed herein, and then heating and drying the resin composition and thereby semi-curing it (conversion into B-stage). The solid content of the resin composition deposited in the fibrous base material after being dried is preferably 20 to 90 mass % to the prepreg. The solid content is more preferably, 30 to 80 mass %, and still more preferably, 40 to 70 mass %. For example, the prepreg can be manufactured by impregnating or coating a fibrous base material with the composition disclosed herein so that the solid content of the resin composition in the prepreg becomes 20 to 90 mass %, and then heating and drying it at a temperature of, for example, 40 to 250° C. for 1 to 30 minutes and thereby semi-curing it (conversion into B-stage).

As the fibrous base material, known materials can be used without limitation, and its examples include organic fibers, inorganic fibers, and glass fibers. Examples of organic fibers include polyimide, polyester, tetrafluoroethylene, and wholly aromatic polyamide. Examples of inorganic fibers include carbon fibers. Examples of the glass fibers include E glass cloth, D glass cloth, S glass cloth, Q glass cloth, NE glass cloth, L glass cloth, T glass cloth, spherical glass cloth, and low dielectric glass cloth. Among them, E glass cloth, T glass cloth, S glass cloth, Q glass cloth, and organic fiber are suitable in view of the low thermal expansion coefficient. Only one may fibrous base material be independently used, or two or more fibrous base materials may be used in combination.

The shape of the fibrous base material can be selected as appropriate according to the intended use and performance. Examples include woven fabric, nonwoven fabric, roving, a chopped strand mat, and a surfacing mat. Examples of weaving of woven fabric include plain weaving, smooth weaving, and twill weaving. It can be selected and designed arbitrarily according to the desired characteristics. The thickness of the fibrous base material is, for example, in the range of about 0.01 to 1.0 mm. In order to reduce the thickness, it is preferably 500 μm or smaller, and more preferably 300 μm or smaller.

If necessary, the fibrous base material may be surface-treated with a silane coupling agent or the like, or mechanically subjected to a fiber-opening process in order to achieve the desired characteristics. Further, a corona treatment or a plasma treatment may be performed. Examples of the surface treatment of the silane coupling agent include an aminosilane coupling treatment, a vinyl silane coupling treatment, a cationic silane coupling treatment, and an epoxy silane coupling treatment.

The method for impregnating the fibrous base material with the resin composition is not limited to any particular method. Examples include a method for preparing a varnish-like resin composition by using an organic solvent such as alcohols, ethers, acetals, ketones, esters, alcohol esters, ketone alcohols, ether alcohols, ketone ethers, ketone esters, or ester ethers, and then immersing the fibrous base material in the varnish, a method for coating the fibrous base material with varnish or spraying vanish onto the fibrous base material, or a method for laminating a film made of the resin composition on each of both surfaces of the fibrous base material.

Further, the resin composition layer formed from the composition disclosed herein, its cured article layer or the like are suitable for insulating layers, underfills, adhesives, and the like of semiconductor chip packages. Further, they are also suitable for compositions for copper clad laminates, bonding sheets for forming wiring boards, and cover coats for flexible substrates.

### 5. Method for Manufacturing Cured Article

A cured article is obtained by subjecting the composition disclosed herein to a curing process. When the composition disclosed herein contains a thermosetting compound, it is cured by a thermosetting treatment, and when the composition disclosed herein contains a photosetting compound, it is cured by a light irradiation treatment. Examples of the method include a method for molding a resin composition into a desired shape such as a sheet and performing a curing process. A cured article may be formed by applying and drying a resin composition containing a solvent and thereby easily obtaining a molded article of the resin composition such as a sheet thereof, and then curing it. The curing timing can be before the molding, during the molding, or after the molding. Note that a sheet-like cured article is also called a cured layer.

The temperature of the heat curing process may be selected as appropriate according to the type of the curable compound. As an example, there is a method in which a heat treatment is performed at a temperature of 150 to 300° C. for 30 to 180 minutes. In the case of the photocuring process, an active light beam is applied with intensity with which it is cured. During the curing, thermocompression bonding (e.g., 2 MPa) can be performed by applying a pressure as required. A crosslinked structure is formed in the composition disclosed herein by the curing process, so that a three-dimensionally crosslinked cured article is obtained.

6. Cured Article and Substrate with Cured Article

Since the cured article obtained from the copolymer disclosed herein is excellent in the heat resistance, the crack resistance after a heat cycle test, and the substrate processability during the manufacturing process, it is suitable as a cured article for various components including a metal clad laminated plate and a printed wiring board, or a substrate with the cured article.

A metal clad laminated plate is obtained, for example, through a series of processes in which an insulating layer is formed by using the composition disclosed herein, and then the insulating layer and a metal layer are laminated. An adhesive sheet or a prepreg formed from the composition disclosed herein is suitably used for this insulating layer. For example, a metal clad laminate can be obtained by laminating a metal layer and a prepreg formed by using the composition disclosed herein, and carrying out a curing process by a heat compression bonding step. A known method can be used for the heat compression bonding step. For example, heat pressing is performed at a temperature of 120 to 250° C. and a pressure of 0.5 to 10 MPa for 0.5 to 5 hours.

Examples of the laminating structure of the metal clad laminate include a laminate consisting of two layers consisting of “metal layer/cured layer”, a laminate consisting of a plurality of layers consisting of “metal layer/cured layer/metal layer”, or a metal clad laminate having a multilayer structure in which metal layers and cured layers are alternately laminated such as “metal layer/cured layer/metal layer/cured layer”. Further, an insulating layer other than the cured layer formed from the composition disclosed herein may be included in the laminate. Further, in order to adjust the thickness of the cured layer, a plurality of prepregs or the like may be laminated on one another and cured. Further, a conductive layer other than the metal layer may be laminated.

For example, a circuit board including a circuit pattern layer can be obtained by forming a circuit pattern on a metal layer of a metal clad laminate having a layer structure of “metal layer/cured layer/metal layer”. In the cured layer, through holes and/or vias may be formed by a laser or the like. Vias may be formed by putting an insulating cured layer on a core substrate by a build-up process, and multilayers may be formed. The circuit board can be obtained, for example, by a method in which a metal layer of a metal clad laminate is formed into a desired circuit pattern by a subtractive method, or by forming a desired circuit pattern on one or both surfaces of an insulating layer by an additive method.

A copper foil or the like is used as the metal layer. For a copper clad laminate, there is a process for performing electrolytic copper plating on a surface of a copper foil, removing a resist layer, and then performing etching with a plating liquid such as an alkaline solution. The composition disclosed herein is suitable for use in a copper clad laminate because it has excellent substrate processability such as plating liquid resistance. Further, since the cured article disclosed herein has excellent crack resistance after a heat cycle test and excellent heat resistance, a substrate including a cured article formed by curing the composition disclosed herein can be used in a wide range of uses under various environments.

A printed wiring board can be manufactured by, for example, processing a copper foil in a copper clad laminate by etching or the like, forming a signal circuit and the like, bonding the substrate and a cover film through an adhesive sheet, and performing a curing process step and the like. Further, for example, a flexible printed wiring board can be manufactured through a series of processes such as forming a conductor pattern on an insulating flexible film, forming a protective film thereon through the adhesive sheet disclosed herein, and performing thermocompression bonding. Examples of the flexible film include polyester, polyimide, a liquid crystal polymer, and a PTFE film. Regarding the conductor pattern, as examples, there are a method for forming it by a printing technology and a method for sputtering and plating.

An opening(s) may be formed in the cured layer of the composition disclosed herein formed on one or both surfaces of the printed wiring board by drilling or laser processing, and a via may be formed by filling the opening with a conductive agent. Further, a circuit layer may be formed on the cured layer of the composition disclosed herein. Since the cured article of the composition disclosed herein has excellent plating liquid resistance, it is suitable for manufacturing of a multilayer printed wiring board. The printed wiring board formed by using the composition disclosed herein has excellent processability, excellent heat resistance, and excellent crack resistance after a heat cycle test, and is suitable for various electronic apparatuses such as smartphones and tablet terminals.

Since the copolymer disclosed herein has an excellent electrical insulating property, it is possible to provide a cured article having an excellent insulating property by further using a curable compound having an insulating property for the composition disclosed herein. For example, it is suitably used as an insulating layer forming material on a circuit board (including a cover layer of a printed wiring board, an interlayer insulating layer of a built-up substrate, a bonding sheet, and the like). Further, for example, by using a conductive material in the filler, it can be used as a conductive member of an electronic component. Examples of electronic components include power modules such as power semiconductor devices, LEDs, inverter apparatuses, and the like

Further, by mixing, for example, a thermally conductive filler, as an inorganic filler, with the cured article of the composition disclosed herein, it can be applied to a wide range of uses in which a heat dissipation property is required. For example, by using the moldability of the resin composition, it can be suitably used as a heat dissipation component having a desired shape. In particular, it is useful as a heat dissipation adhesive or a heat dissipation sheet for an electronic apparatus (a smartphone and a tablet terminal) in which a fan and a heat sink cannot be provided due to the reduction in weight and thickness, and for an exterior material for a battery. Further, the cured article of the composition disclosed herein is also suitable as an adhesive layer between a heating element and a heat sink, or as a heat spreader. Further, it can also be applied as a heat dissipation layer covering one or a plurality of types electronic components mounted on a substrate.

The amount of the copolymer disclosed herein to be mixed is arbitrarily determined. However, it is preferably contained in 1 to 50 mass % based on 100 mass % of the nonvolatile content (solid content) of the composition disclosed herein in order to improve the heat resistance of the cured article and the crack resistance after a heat cycle test even further. The aforementioned range is more preferably 4 to 44 mass % and still more preferably 6 to 38 mass %.

### Examples

The present disclosure will be described hereinafter in a more specific manner by using examples. The present disclosure is not limited to the below-shown examples. Unless otherwise specified, “%” and “parts” are based of the mass.

### 7. Method Measurement

### 7-1. Measurement of Acid Anhydride Value

In a glass-stoppered conical flask, about 1 g of a sample (a resin of each synthetic example) was accurately weighed and dissolved in 100 mL of a 1,4-dioxane solvent. 10 mL of a mixed solution of octylamine, which was larger than the amount of the acid anhydride group in the sample, 1,4-dioxane, and water (mass mixing ratio is 1.49/800/80) was added and stirred for 15 minutes, so that they were reacted with the acid anhydride group. After that excessive octylamine was titrated with a mixed solution of 0.02M perchloric acid and 1,4-dioxane. Further, 10 mL of a mixed solution of octylamine, 1,4-dioxane, and water (mass mixing ratio is 1.49/800/80), to which no sample was added, was also measured as a blank. An acid anhydride value was calculated by the below-shown formula (unit: mgKOH/g).

$$Acid anhydride value ( mg KOH / g ) = 0.02 \times ( B - A ) \times F \times 56.11 / S$$

B: Titration amount of blank (mL)
A: Titration amount of sample (mL)
S: Amount of collected sample (g)
F: Titer of 0.02 mol/L perchloric acid

### 7-2. Measurement of Amine Value

In a glass-stoppered conical flask, about 1 g of a sample (resin of each synthesis example) was accurately weighed and dissolved in 100 mL of a cyclohexanone solvent. To this solution, two or three drops of an indicator prepared by separately mixing a solution obtained by dissolving 0.20 g of Methyl Orange in 50 mL of distilled water and a solution obtained by dissolving 0.28 g of Xylene Cyanol FF in 50 mL of methanol were added, and they were kept for 30 seconds. After that, the solution was titrated with a 0.1 N alcoholic hydrochloric acid solution until the solution had a grayish blue color. The amine value was determined by the below-shown formula.

$$Amine value ( mg KOH / g ) = ( 5.611 \times a \times F ) / S$$

where,
S: Amount of collected sample (g)
a: Amount of consumed 0.1 N alcoholic hydrochloric acid solution (mL)
F: Titer of 0.1 N alcoholic hydrochloric acid solution

### 7-3. Measurement of Weight Average Molecular Weight (Mw)

Mw was measured by using GPC (Gel Permeation Chromatography) “GPC-101” manufactured by Showa Denko K.K. THF (tetrahydrofuran) was used as the solvent, and two “KF-805L” (GPC column manufactured by Showa Denko K.K.: 8 mm ID x 300 mm size) connected to each other in series were used as a column. Mw was determined as a polystyrene-converted value under conditions of the sample concentration of 1 mass %, the flow rate of 1.0 mL/min, the pressure of 3.8 MPa, and the column temperature of 40° C. For data analysis, a calibration curve, a molecular weight, and a peak area were calculated by using manufacturer's pre-installed software, and Mw was determined in a retention time range of 17.9 to 30.0 minutes which is the analysis target.

### 7-4. Radically Reactive Non-Conjugated Carbon-Carbon Unsaturated Bond Value of Conditions (i) and (ii)

Radically reactive non-conjugated carbon-carbon unsaturated bond values of Conditions (i) and (ii) were determined from the design values of the raw materials for the polymerization of the copolymer disclosed herein. That is, they were calculated from the amount of the charged compounds bonded by the radically reactive non-conjugated carbon-carbon unsaturated bonds of the conditions (i) and (ii) to the amount of charged raw materials used for the synthesis of the copolymer disclosed herein.

### 7-5. Calculation of Total Functional Value

The total functional value was defined as the sum total (mgKOH/g) of the acid anhydride group value, the amine value, and the radically reactive non-conjugated carbon-carbon unsaturated bond values of the conditions (i) and (ii).

### 8. Synthesis of Copolymer Disclosed Herein

### Synthesis Example 1

48 parts of LICOCENE PP 1602 (polypropylene polyethylene copolymer, (manufactured by Clariant), Mw 57,000, St 0%) were dissolved in 50 parts of xylene. 20 parts of maleic anhydride as an anhydride and 1.7 parts of Loperox DTA (di-t-amyl peroxide, manufactured by ARKEMA Yoshitomi) as a radical initiator were added, and the mixture was stirred for two hours while refluxing the mixture at 140° C. The end point of the reaction was confirmed by the generation of a carboxy group-derived peak (around 1,711 cm⁻¹) by FT-IR, and a maleic anhydride-modified polyethylene polypropylene copolymer was obtained. After that, 0.5 parts of K-NOX 1010 (pentaerythritol tetrakis 3-(3,5-di-tert-butyl-4-hydroxyphenyl) propionate manufactured by Kuo Ching Chemical) were added. The temperature was raised to 100° C. 28 parts of 5-norbornene-2-methylamine and 0.08 parts of dimethylbenzylamine as a catalyst were added. The mixture was stirred at 100° C. for two hours, and then imidized by stirring it at 170° C. for two hours while azeotrophizing xylene and water generated by the reaction. The end point of the reaction was confirmed by the shift of the carboxy group-derived peak (around 1,711 cm⁻¹) to an imide group-derived peak (around 1,704 cm⁻¹) by FT-IR and the generation of an alkane-derived peak (around 1,397 cm⁻¹). After that, the mixture was diluted by adding 200 parts of toluene, and a precipitate was obtained by adding 225 parts of methanol. The precipitate was collected by filtration. The precipitate was dissolved by adding 200 parts of toluene again. The precipitate was obtained by adding 225 parts of methanol. The precipitate was collected by filtration and dried in a vacuum oven at 100° C. for two hours, and as a result, a resin having a non-conjugated carbon-carbon unsaturated bond in a side chain was obtained. The carbon-carbon unsaturated bond value for radical reactivity is 10 mgKOH/g.

### Synthesis Examples 2 to 8

Synthesis Examples 2 to 8 of copolymers were obtained by the same method as Synthesis Example 1, except that the monomers and the mixing amounts were changed to those listed in Table 1.

### Comparative Synthesis Example 1

48 parts of LICOCENE PP 1602 were dissolved in 50 parts of xylene. 20 parts of maleic anhydride as an acid anhydride and 1.7 parts of Loperox DTA as a radical initiator were added, and the mixture was stirred for two hours while refluxing the mixture at 140° C. After that, the mixture was diluted by adding 200 parts of toluene, and a precipitate was obtained by adding 225 parts of methanol. The precipitate was collected by filtration. The precipitate was dissolved by adding 200 parts of toluene again. The precipitate was obtained by adding 225 parts of methanol. The precipitate was collected by filtration and dried in a vacuum oven at 100° C. for two hours, and as a result, a resin having an acid anhydride in a side chain was obtained. The acid anhydride value was 10 mgKOH/g.

### Comparative Synthesis Example 2 to 7

Comparative Synthesis Example 2 to 7 of copolymers were obtained by the same method as Comparative Synthesis Example 1, except that the monomers and the mixing amounts were changed to those listed in Table 1.

Abbreviations of Table 1 are shown below.

(Resin which has not Yet been Modified)
R-1: Polypropylene (LICOCENE PP 1602, Mw 57,000, St 0%)
R-2: Hydrogenated styrene-butadiene rubber (Dynaron 2324P, Mw 170,000, St 16%)
R-3: SEP (G1702, Mw 150,000, St 28%)
R-4: SEBS (G1652, Mw 72,000, St 30%)
R-5: SEBSS (A1536, Mw 130,000, St 40%)

### (Non-Conjugated Carbon-Carbon Unsaturated Bond-Containing Compound)

T-1: 5-norbornene-2-methylamine
T-2: N-(4-aminophenyl) maleimide

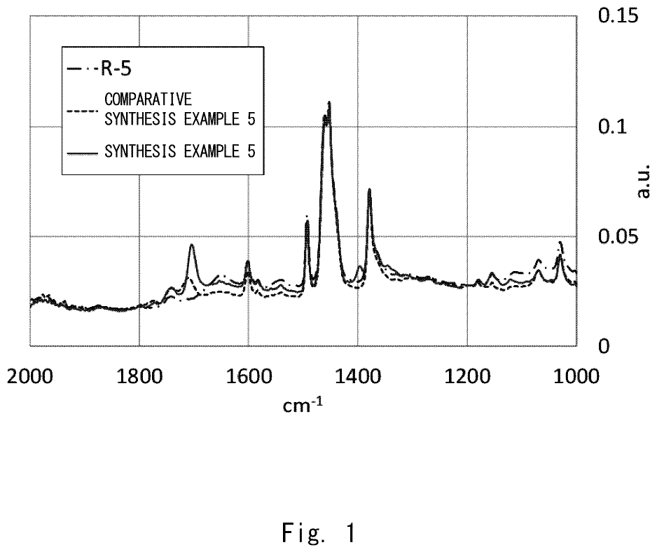

FIG. 1 shows IR spectra of a resin R-5 which has not yet been modified, Comparative Synthesis Example 5, and Synthesis Example 5. As shown in the figure, a carboxy group-derived peak (around 1,711 cm⁻¹) was confirmed in Comparative Synthesis Example 5. Meanwhile, in Synthesis Example 5, it was confirmed that a peak derived from C═O of the carboxylic acid (around 1,711 cm⁻¹) had shifted to a peak derived from C═O of the imide group (around 1,704 cm⁻¹). Further, an alkane-derived peak (around 1,397 cm⁻¹) was confirmed.

TABLE 1

| | | Synthesis Example | | | | | | | | Comparative Synthesis Example | | | | | | |
|---|---|---|---|---|---|---|---|---|---|---|---|---|---|---|---|---|
| | | 1 | 2 | 3 | 4 | 5 | 6 | 7 | 8 | 1 | 3 | 3 | 4 | 5 | 6 | 7 |
| Resin before | R-1 | 48 | | | | | | | | 48 | | | | | | |
| being modified | R-2 | | 48 | | | | | | | | 48 | | | | | |
| | R-3 | | | 48 | | | | | | | | 48 | | | | |
| | R-4 | | | | 48 | | | | | | | | 48 | | | |
| | R-5 | | | | | 48 | 48 | 48 | 48 | | | | | 48 | 48 | 48 |
| Solvent | Xylene | 50 | 50 | 50 | 50 | 50 | 50 | 50 | 50 | 50 | 50 | 50 | 50 | 50 | 50 | 50 |
| Acid anhydride | Maleic | 20 | 15 | 2 | 2 | 2 | 0.25 | 10 | 2 | 20 | 15 | 2 | 2 | 2 | 0.25 | 10 |
| | anhydride | | | | | | | | | | | | | | | |
| Radical initiator | Ruperox DTA | 1.7 | 1.7 | 1.7 | 1.7 | 1.7 | 1.7 | 1.7 | 1.7 | 1.7 | 1.7 | 1.7 | 1.7 | 1.7 | 1.7 | 1.7 |
| Antioxidant | K-NOX 1010 | 0.5 | 0.5 | 0.5 | 0.5 | 0.5 | 0.5 | 0.5 | 0.5 | | | | | | | |
| Non-conjugated | T-1 | 28 | 21 | 2.8 | 2.8 | 2.8 | 0.28 | 14 | | | | | | | | |
| carbon-carbon | T-2 | | | | | | | | 4.3 | | | | | | | |
| unsaturated bond | | | | | | | | | | | | | | | | |
| Catalyst | Dimethyl- | 0.08 | 0.08 | 0.08 | 0.08 | 0.08 | 0.08 | 0.08 | 0.08 | | | | | | | |
| | benzylamine | | | | | | | | | | | | | | | |

| | | | | | | | | | | | | | | | |
|---|---|---|---|---|---|---|---|---|---|---|---|---|---|---|---|
| Radically reactive non-conjugated | 10 | 10 | 10 | 10 | 10 | 1 | 50 | 10 | 0 | 0 | 0 | 0 | 0 | 0 | 0 |
| carbon-carbon unsaturated bond | | | | | | | | | | | | | | | |
| [mgKOH/g] | | | | | | | | | | | | | | | |
| Acid anhydride value [mgKOH/g] | 0 | 0 | 0 | 0 | 0 | 0 | 0 | 0 | 10 | 10 | 10 | 10 | 10 | 1 | 50 |
| Amine Value [mgKOH/g] | 0 | 0 | 0 | 0 | 0 | 0 | 0 | 0 | 0 | 0 | 0 | 0 | 0 | 0 | 0 |

### 9. Preparation of Resin Composition (Varnish)

### Example 1

100 parts of the copolymer disclosed herein (P1) of Synthesis Example 1 in the solid content and 1 part of (C)-1 as an initiator were charged into a container. Then, a varnish according to Example 1 was prepared by adding a mixed solvent (toluene:MEK=1:1 (mass ratio)) so that the concentration of the nonvolatile content became 25% and stirring the mixture for 10 minutes by a dispar.

### Examples 2 to 31, Comparative Examples 1 to 22

Varnishes according to Examples 2 to 31 and Comparative Examples 1 to 22 were prepared by the same method as in Example 1, except that the components to be mixed and the mixing amounts thereof were changed to those listed in Tables 2 and 3.

Materials used in the examples and the comparative Examples are shown below.

### (Curable Compound)

(B)-1: Epoxy compound (b1), XD-1000 (manufactured by Nippon Kayaku Co., Ltd., dicyclopentadiene-type epoxy, multifunctional, functional group equivalent 252 g/eq)
(B)-2: Cyanate ester compound (b2), BAD (manufactured by Mitsubishi Gas Chemical Company, Inc., bisphenol A-type cyanate ester, bifunctional, functional group equivalent 139 g/eq, molecular weight 278)
(B)-3: Maleimide compound (b3), BMI-4000 manufactured by Daiwa Kasei Industrial Co., Ltd., bisphenol A diphenyl ether bismaleimide, bifunctional, functional group equivalent 285.3 g/eq, molecular weight 570.6)
   (B)-4: Allyl group-containing compound (b4), TAIC (manufactured by Shinryo Corporation, triallyl isocyanurate, trifunctional, molecular weight 249.3)
(B)-5: Vinyl group-containing compound (b5), OPE-2St 1200 (manufactured by Mitsubishi Gas Chemical Company, Inc., vinylbenzyl-modified polyphenylene ether, bifunctional, functional group equivalent 590 g/eq, number average molecular weight 1,180)
(B)-6: (meth)acrylate group-containing compound (b6), Noryl SA9000 (manufactured by SABIC, methacrylate group-containing polyphenylene ether, bifunctional, functional group equivalent 850 g/eq, number average molecular weight 1,700)
(B)-7: Benzoxazine compound (b7), 3,3′-(methylene-1,4-diphenylene) bis(3,4-dihydro-2H-1,3-benzoxazine) (manufactured by Shikoku Chemical Corporation, P-d-type benzoxazine), bifunctional, oxazine equivalent amount 217)

### (Initiator (C))

(C)-1: Radical initiator (c1), PERCUMYL D (manufactured by NOF corporation, dicumyl peroxide, molecular weight 270.4)
(C)-2: Epoxy initiator (c2), TETRAD-X (manufactured by Mitsubishi Gas Chemical Company, Inc., polyfunctional epoxy resin, molecular weight 360.5)

Note that the epoxy initiator (c2) can be classified into the epoxy compound (b1) in that it has an epoxy group. However, in this example, the epoxy initiator (c2) is classified into the initiators (C) because it is mainly used as an initiator to open the ring of an epoxy by an amine structure.

### (Filler (D))

(D)-1: SO-C2 (average particle diameter 0.4 to 0.6 μm, manufactured by Admatex, silica)
(D)-2: AO-509 (average particle diameter 7 to 13 μm, manufactured by Admatex, alumina)
(D)-3: SP-2 (average particle diameter D50 4 μm, manufactured by Denka, boron nitride)
(D)-4: HF-01 (average particle diameter D50 1.1 μm, manufactured by Tokuyama Corporation, aluminum nitride) (Olefinic polymer (E) containing radically reactive carbon-carbon unsaturated bond in side chain)
(E)-1: Styrene-butadiene-styrene resin (TUFPRENE 126S, manufactured by Asahi Kasei Corporation)
(E)-2: Polybutadiene resin (PB B-3000, manufactured by Nippon Soda Co., Ltd.)

### 10. Manufacturing of Evaluation Sample

### 10-1. Manufacturing of Adhesive Sheet

For each example, the resin varnish according to the example was uniformly coated on a high release-strength film having a thickness of 50 μm (polyethylene terephthalate (PET) film coated with a high release-strength agent) by using a doctor blade so that the thickness after being dried became 50 μm, and then dried at 100° C. for 2 minutes. After that, it was cooled to a room temperature, and as a result, an adhesive sheet with a release film on one surface were obtained. Next, the obtained adhesive sheet with the release film on one surface was put over a low-release-strength film having a thickness of 50 μm (polyethylene terephthalate (PET) film coated with a low-release-strength agent) in such a manner that of the adhesive sheet surface of the adhesive sheet faced, i.e., was in contact with, the low-release-strength film, and as a result, an adhesive sheet with release films on both surfaces, having a structure of “high release-strength film/adhesive sheet/low-release-strength film” was obtained.

### 10-2. Manufacturing of Copper-Clad Laminate

The low-release-strength film was peeled off from the adhesive sheet with release films on both surfaces, obtained by the above-described method. The exposed adhesive sheet surface was temporarily bonded to a copper foil side of a one-surface copper clad laminate, which was obtained by laminating a polyimide film having a thickness of 50 μm and a copper foil having a thickness of 12 μm on each other, by using a vacuum laminator (small pressurized-type vacuum laminator V-130 manufactured by Nikko-Materials Co., Ltd.). Note that the conditions for the vacuum laminate were as follows: heating temperature 100° C., vacuum time 60 seconds, vacuum pressure 2 hPa, pressure 0.4 MPa, and pressurization time 60 seconds.

Next, the high release-strength film was peeled off, and a polyimide film side of the second one surface copper clad laminate was temporarily bonded to the exposed adhesive sheet surface by using a vacuum laminator. Then, the adhesive sheet was thermally cured at 200° C. and 2 MPa for two hours by using a vacuum heat press, and as a result, an evaluation sample having a laminating structure of “polyimide film/copper foil/adhesive sheet of cured article/polyimide film/copper foil film” was manufactured.

### 11. Evaluation

### α. Heat Resistance

For each example, a piece having a width of 10 mm and a length of 65 mm was cut out from the copper clad laminate manufactured in the example. The test piece was stored under various conditions. After that, the copper foil surface was brought into contact with molten solder at various temperatures and floated for 1 minute. After that, the appearance of the test piece was visually observed, and the test piece was evaluated for the presence of an abnormality in regard to the adhesion of the cured adhesive layer, such as foaming, floating, and peeling thereof. In this test, the thermal stability of the cured adhesive layer upon being brought into contact with solder was evaluated by the appearance. While the appearances of those having satisfactory heat resistance do not change, foaming and/or peeling occur in those having poor heat resistance after the soldering process. These evaluation results were determined according to the below-shown criteria.
AA: After 24 hours of storage under an atmosphere of a temperature of 85° C. and a relative humidity of 85%, there was no change in the appearance when being floated in molten solder having a temperature of 300° C.
A: The above-described condition AA was not satisfied. After 24 hours of storage under an atmosphere of a temperature of 40° C. and a relative humidity of 90%, there was no change in the appearance when being floated in molten solder having a temperature of 300° C.
B: The above-described condition A was not satisfied. After 24 hours of storage of the test piece under an atmosphere of a temperature of 40° C. and a relative humidity of 90%, there was no change in the appearance when being floated in molten solder having a temperature of 280° C.
C: The above-described conditions A and B were not satisfied. After 24 hours of storage under of the test piece under an atmosphere of a temperature of 23° C. and a relative humidity of 50%, there was no change in the appearance when being floated in molten solder having a temperature of 280° C.
D: The above-described conditions A to C were not satisfied. After 24 hours of storage of the test piece under an atmosphere of a temperature of 23° C. and a relative humidity of 50%, there was no change in the appearance when being floated in molten solder having a temperature of 260° C.
E: The above-described conditions A to D were not satisfied. After 24 hours of storage of the test piece under an atmosphere of a temperature of 23° C. and a relative humidity of 50%, there was no change in the appearance when being floated in molten solder having a temperature of 240° C.
F: After 24 hours of storage of the test piece under an atmosphere of a temperature of 23° C. and a relative humidity of 50%, a change occurred in the appearance when being floated in molten solder having a temperature of 240° C. There is a problem in practical use.

### β. Dielectric Characteristic

After the adhesive sheet with release films on both surfaces was stored for 24 hours or longer under an atmosphere of a temperature of 23° C. and a relative humidity of 50%, the release film was peeled off. The dielectric loss tangent (Df) at a measurement frequency of 10 GHz was determined by a cavity resonator method by using a dielectric-constant measuring apparatus manufactured by AET, INC. under an environment of the same temperature and the same humidity.
AA: Df is smaller than 0.0004
A: Df is larger than 0.0004 and smaller than 0.0005
B: Df is larger than 0.0005 and smaller than 0.0010
C: Df is larger than 0.0010 and smaller than 0.0020
D: Df is larger than 0.0020 and smaller than 0.0030
E: Df is larger than 0.0030 and smaller than 0.0035
F: Df is 0.0035 or more. There is a problem in practical use.

### γ. Evaluation of Stress Relaxation (Crack Resistance) Characteristic

A glass fabric base material epoxy resin copper clad laminate in which a circuit pattern having L/S=25 μm/25 μm and a copper thickness of 25 μm and 50 μm, respectively, was formed was prepared as an inner-layer circuit board. For each example, the resin sheet according to the example manufactured by the above-described method was heated and pressed on each of both surfaces in vacuum for two hours under conditions of 200° C. and 3.0 MPa. Lastly, copper foils were placed on the outermost layers on both sides, and as a result, an evaluation printed wiring board was obtained. Then, the evaluation printed wiring board was put into a thermal shock apparatus (“TSE-11-A”, manufactured by Espec), and alternating exposure was carried out a predetermined number of times under the exposure conditions: exposure to high temperature: 125° C., 15 minutes, and exposure to low temperature: −50° C., 15 minutes. The evaluation printed wiring board was cut, and the exposed cross section was observed for the presence of a crack at a magnification of a factor of 5,000 by using a scanning electron microscope (SEM). Note that a crack is one having a size of 0.1 μm or larger. The evaluation criteria are shown below.
AA: No crack occurred after 4,000 heat cycle tests. Very good result.
A: The above-described condition AA is not satisfied. No crack occurred after 3,000 heat cycle tests. Very good result.
B: The above-described condition A is not satisfied. No crack occurred after 1,000 heat cycle tests. Very good result.
C: The above-described condition A and B are not satisfied. No crack occurred after 200 heat cycle tests. Good result.
D: The above-described conditions A to C are not satisfied. No crack occurred after 100 heat cycle tests. There is a problem in practical use.
E: Crack occurred before 100 heat cycle tests. There is a problem in practical use.

TABLE 2

| | | 3 | 4 | 5 | 6 | 7 | 8 | 9 | 10 | 11 | 12 | 13 | 14 | 15 | 16 | 17 |
|---|---|---|---|---|---|---|---|---|---|---|---|---|---|---|---|---|
| | Synthesis | 100 | | | | | | | | 100 | | | | | | |
| | Example 3 | | | | | | | | | | | | | | | |
| | Synthesis | | 100 | | | | | | | | 100 | | | | | |
| | Example 4 | | | | | | | | | | | | | | | |
| | Synthesis | | | 100 | | | | | | | | 100 | | | | 100 |
| | Example 5 | | | | | | | | | | | | | | | |
| | Synthesis | | | | 100 | | | | | | | | 100 | | | |
| | Example 6 | | | | | | | | | | | | | | | |
| | Synthesis | | | | | 100 | | | | | | | | 100 | | |
| | Example 7 | | | | | | | | | | | | | | | |
| | Synthesis | | | | | | 100 | | | | | | | | 100 | |
| | Example 8 | | | | | | | | | | | | | | | |
| Curable | (B)-1 | | | | | | | | | | | | | | | 400 |
| compound | (B)-2 | | | | | | | | | | | | | | | |
| (B) | (B)-3 | | | | | | | 400 | 400 | 400 | 400 | 400 | 400 | 400 | 400 | |
| | (B)-4 | | | | | | | | | | | | | | | |
| | (B)-5 | | | | | | | | | | | | | | | |
| | (B)-6 | | | | | | | | | | | | | | | |
| | (B)-7 | | | | | | | | | | | | | | | |
| Initiator | (C)-1 | 1 | 1 | 1 | 1 | 1 | 1 | 1 | 1 | 1 | 1 | 1 | 1 | 1 | 1 | 1 |
| (C) | (C)-2 | | | | | | | | | | | | | | | 3 |
| Filler (D) | (D)-1 | | | | | | | | | | | | | | | |
| | (D)-2 | | | | | | | | | | | | | | | |
| | (D)-3 | | | | | | | | | | | | | | | |
| | (D)-4 | | | | | | | | | | | | | | | |

| | | | | | | | | | | | | | | | |
|---|---|---|---|---|---|---|---|---|---|---|---|---|---|---|---|
| Heat resistance | D | D | D | D | D | D | E | D | C | C | B | C | B | B | E |
| Dielectric characteristic | D | C | C | C | D | D | C | D | D | D | D | D | D | D | E |
| Stress relaxation | A | A | A | A | A | A | C | B | A | A | A | A | A | A | A |

| | | 18 | 19 | 20 | 21 | 22 | 23 | 24 | 25 | 26 | 27 | 28 | 29 | 30 | 31 |
|---|---|---|---|---|---|---|---|---|---|---|---|---|---|---|---|
| | Synthesis | | | | | | | | | | | | | | |
| | Example 3 | | | | | | | | | | | | | | |
| | Synthesis | | | | | | | | | | | | | | |
| | Example 4 | | | | | | | | | | | | | | |
| | Synthesis | 100 | 100 | 100 | 100 | 100 | 100 | 100 | 100 | 100 | 100 | 100 | 100 | 100 | 100 |
| | Example 5 | | | | | | | | | | | | | | |
| | Synthesis | | | | | | | | | | | | | | |
| | Example 6 | | | | | | | | | | | | | | |
| | Synthesis | | | | | | | | | | | | | | |
| | Example 7 | | | | | | | | | | | | | | |
| | Synthesis | | | | | | | | | | | | | | |
| | Example 8 | | | | | | | | | | | | | | |
| Curable | (B)-1 | | | | | | | | | | | | | | |
| compound | (B)-2 | 400 | | | | | 73 | | | | | | | | |
| (B) | (B)-3 | | | | | | 327 | 327 | 327 | 327 | 327 | 400 | 400 | 400 | 400 |
| | (B)-4 | | 400 | | | | | 73 | | | | | | | |
| | (B)-5 | | | 400 | | | | | 73 | | | | | | |
| | (B)-6 | | | | 400 | | | | | 73 | | | | | |
| | (B)-7 | | | | | 400 | | | | | 73 | | | | |
| Initiator | (C)-1 | 1 | 1 | 1 | 1 | 1 | 1 | 1 | 1 | 1 | 1 | 1 | 1 | 1 | 1 |
| (C) | (C)-2 | | | | | | | | | | | | | | |
| Filler (D) | (D)-1 | | | | | | | | | | | 500 | | | |
| | (D)-2 | | | | | | | | | | | | 500 | | |
| | (D)-3 | | | | | | | | | | | | | 500 | |
| | (D)-4 | | | | | | | | | | | | | | 500 |

| | | | | | | | | | | | | | | |
|---|---|---|---|---|---|---|---|---|---|---|---|---|---|---|
| Heat resistance | D | D | D | E | C | A | A | A | A | A | B | B | B | B |
| Dielectric characteristic | D | D | E | E | D | D | C | D | D | C | C | C | C | C |
| Stress relaxation | A | A | AA | AA | A | A | A | AA | AA | A | AA | AA | AA | A |

TABLE 3

| | | Comparative Examples | | | | | | | | | | |
|---|---|---|---|---|---|---|---|---|---|---|---|---|
| | | 1 | 2 | 3 | 4 | 5 | 6 | 7 | 8 | 9 | 10 | 11 |
| Oxygen | Comparative | 100 | | | | | | | 100 | | | |
| modified | Synthesis | | | | | | | | | | | |
| resin (A) | Example 1 | | | | | | | | | | | |
| | Comparative | | 100 | | | | | | | 100 | | |
| | Synthesis | | | | | | | | | | | |
| | Example 2 | | | | | | | | | | | |
| | Comparative | | | 100 | | | | | | | 100 | |
| | Synthesis | | | | | | | | | | | |
| | Example 3 | | | | | | | | | | | |
| | Comparative | | | | 100 | | | | | | | 100 |
| | Synthesis | | | | | | | | | | | |
| | Example 4 | | | | | | | | | | | |
| | Comparative | | | | | 100 | | | | | | |
| | Synthesis | | | | | | | | | | | |
| | Example 5 | | | | | | | | | | | |
| | Comparative | | | | | | 100 | | | | | |
| | Synthesis | | | | | | | | | | | |
| | Example 6 | | | | | | | | | | | |
| | Comparative | | | | | | | 100 | | | | |
| | Synthesis | | | | | | | | | | | |
| | Example 7 | | | | | | | | | | | |
| Curable | (B)-1 | | | | | | | | | | | |
| compound (B) | (B)-2 | | | | | | | | | | | |
| | (B)-3 | | | | | | | | | | | |
| | (B)-4 | | | | | | | | | | | |
| | (B)-5 | | | | | | | | | | | |
| | (B)-6 | | | | | | | | | | | |
| Initiator (C) | (C)-1 | 1 | 1 | 1 | 1 | 1 | 1 | 1 | | | | |
| | (C)-2 | | | | | | | | 3 | 3 | 3 | 3 |
| Olefinic polymer | (E)-1 | | | | | | | | | | | |
| containing radically | (E)-2 | | | | | | | | | | | |
| reactive carbon- | | | | | | | | | | | | |
| carbon unsaturated | | | | | | | | | | | | |
| bond in side | | | | | | | | | | | | |
| chain (E) | | | | | | | | | | | | |
| Heat resistance | | F | F | F | F | F | F | F | F | E | D | D |
| Dielectric characteristic | | D | F | F | E | E | E | F | E | F | F | F |
| Stress relaxation | | C | B | A | A | A | A | A | D | C | B | B |
| | | Comparative Examples | | | | | | | | | | |
| | | 12 | 13 | 14 | 15 | 16 | 17 | 18 | 19 | 20 | 21 | 22 |
| Oxygen | Comparative | | | | | | | | | | | |
| modified | Synthesis | | | | | | | | | | | |
| resin (A) | Example 1 | | | | | | | | | | | |
| | Comparative | | | | 100 | | | | | | | |
| | Synthesis | | | | | | | | | | | |
| | Example 2 | | | | | | | | | | | |
| | Comparative | | | | | 100 | | | | | | |
| | Synthesis | | | | | | | | | | | |
| | Example 3 | | | | | | | | | | | |
| | Comparative | | | | | | 100 | | | | | |
| | Synthesis | | | | | | | | | | | |
| | Example 4 | | | | | | | | | | | |
| | Comparative | 100 | | | | | | 100 | | | | |
| | Synthesis | | | | | | | | | | | |
| | Example 5 | | | | | | | | | | | |
| | Comparative | | 100 | | | | | | 100 | | | |
| | Synthesis | | | | | | | | | | | |
| | Example 6 | | | | | | | | | | | |
| | Comparative | | | 100 | | | | | | 100 | | |
| | Synthesis | | | | | | | | | | | |
| | Example 7 | | | | | | | | | | | |
| Curable | (B)-1 | | | | 400 | 400 | 400 | 400 | 400 | 400 | | |
| compound (B) | (B)-2 | | | | | | | | | | | |
| | (B)-3 | | | | | | | | | | | |
| | (B)-4 | | | | | | | | | | | |
| | (B)-5 | | | | | | | | | | | |
| | (B)-6 | | | | | | | | | | | |
| Initiator (C) | (C)-1 | | | | | | | | | | 1 | 1 |
| | (C)-2 | 3 | 3 | 3 | 3 | 3 | 3 | 3 | 3 | 3 | | |
| Olefinic polymer | (E)-1 | | | | | | | | | | 100 | |
| containing radically | (E)-2 | | | | | | | | | | | 100 |
| reactive carbon- | | | | | | | | | | | | |
| carbon unsaturated | | | | | | | | | | | | |
| bond in side | | | | | | | | | | | | |
| chain (E) | | | | | | | | | | | | |

| | | | | | | | | | | | |
|---|---|---|---|---|---|---|---|---|---|---|---|
| Heat resistance | C | D | C | F | F | F | E | F | E | F | F |
| Dielectric characteristic | F | F | F | F | F | F | F | F | F | F | F |
| Stress relaxation | B | B | B | C | B | B | B | B | B | B | B |

This application is based upon and claims the benefit of priorities from Japanese patent applications No. 2023-028746, filed on Feb. 27, 2023, and No. 2023-202239, filed on Nov. 29, 2023, the disclosures of both of which are incorporated herein in their entirety by reference.

1-14. (canceled)

15. A modified olefinic copolymer in which a principal chain contains a structural unit derived from a conjugated diene compound and/or a structural unit derived from an alicyclic or chain-like non-conjugated olefin compound, wherein
the modified olefinic copolymer comprising: a monocyclic structure and/or a polycyclic structure in at least one of a side group, a side chain, and a molecular chain end, and
a ring of the monocyclic structure and/or one of rings of the polycyclic structure is at least one of an alicyclic skeleton consisting of carbon atoms and an alicyclic skeleton consisting of carbon and hetero atoms, and satisfies at least one of below-shown conditions (i) and (ii):
(i) the alicyclic skeleton has a radically reactive non-conjugated carbon-carbon unsaturated bond; and
(ii) a carbon atom constituting the alicyclic skeleton and a carbon atom not constituting the ring bonded to the carbon atom are bonded to each other by a radically reactive non-conjugated carbon-carbon unsaturated bond.

16. The modified olefinic copolymer according to claim 15, wherein the principal chain has substantially no unsaturated bond except for the molecular chain end.

17. The modified olefinic copolymer according to claim 15, wherein the principal chain contains a structural unit derived from an aromatic vinyl compound.

18. The modified olefinic copolymer according to claim 15, further containing a block consisting of a structural unit derived from an aromatic vinyl compound and a block consisting of a structural unit derived from a conjugated diene compound.

19. The modified olefinic copolymer according to claim 17, wherein the block consisting of the structural unit derived from the conjugated diene compound further contains a structural unit derived from an aromatic vinyl compound.

20. The modified olefinic copolymer according to claim 15, wherein the modified olefinic copolymer is a hydrogenated styrene-based elastomer, and is a modified form of one of a styrene-ethylene-butylene block copolymer (SEB), a styrene-ethylene-propylene block copolymer (SEP), a styrene-ethylene-butylene-styrene block copolymer (SEBS), a styrene-ethylene-propylene-styrene block copolymer (SEPS), a styrene-ethylene-butylene styrene-styrene block copolymer (SEBSS), a styrene-isobutylene-styrene block copolymer (SIBS), and a styrene-ethylene-ethylene propylene styrene block copolymer (SEEPS).

21. A resin composition containing a modified olefinic copolymer according to claim 15.

22. The resin composition according to claim 21, further containing a curable compound, in which the curable compound contains at least one compound selected from an epoxy compound (b1), a cyanate ester compound (b2), a maleimide compound (b3), an allyl group-containing compound (b4), a vinyl group-containing compound (b5), a (meth)acrylate group-containing compound (b6), and a benzoxazine compound (b7).

23. The resin composition according to claim 21, further containing an inorganic filler.

24. A laminated sheet comprising a base material and a resin composition layer formed on the base material using a resin composition according to claim 21.

25. A prepreg obtained by impregnating a base material with a resin composition according to claim 21.

26. A cured article obtained from a resin composition according to claim 21.

27. A substrate with a cured article obtained by curing a resin composition according to claim 21.

28. An electronic apparatus comprising the substrate with the cured article according to claim 27.
